(19) United States
(12) Patent Application Publication
(10) Pub. No.: US 2023/0402382 A1
(43) Pub. Date: Dec. 14, 2023

(54) SEMICONDUCTOR DEVICE

(71) Applicant: SAMSUNG ELECTRONICS CO., LTD., SUWON-SI (KR)

(72) Inventors: Jin Kyu KIM, Suwon-si (KR); Yun Suk NAM, Suwon-si (KR); Kyoung Woo LEE, Suwon-si (KR); Ho-Jun KIM, Suwon-si (KR); Da Rong OH, Suwon-si (KR); Sung Moon LEE, Suwon-si (KR); Hag Ju CHO, Suwon-si (KR); Seung Min CHA, Suwon-si (KR)

(21) Appl. No.: 18/113,715

(22) Filed: Feb. 24, 2023

(30) Foreign Application Priority Data
Jun. 8, 2022 (KR) 10-2022-0069327

(51) Int. Cl. H01L 23/528; H01L 29/06; H01L 29/66; H01L 29/775; H01L 29/786; H01L 29/423

(52) U.S. Cl. CPC H01L 23/5286; H01L 29/0673; H01L 29/66545; H01L 29/775; H01L 29/78696; H01L 29/66439; H01L 29/42392

(57) ABSTRACT

A semiconductor device includes: a base substrate; a first interlayer insulating layer disposed on the base substrate; a power rail disposed inside the first interlayer insulating layer; an active pattern extended in a first horizontal direction and disposed on the first interlayer insulating layer; a gate electrode extended in a second horizontal direction different from the first horizontal direction and disposed on the active pattern; a gate cut extended in the first horizontal direction and disposed on the power rail, wherein the gate cut separates the gate electrode; and a power rail via disposed inside the gate cut, wherein the power rail via is overlapped by the power rail.

### CROSS-REFERENCE TO RELATED APPLICATION

This application claims priority under 35 U.S.C. 119(a) to Korean Patent Application No. 10-2022-0069327 filed on Jun. 8, 2022 in the Korean Intellectual Property Office, the disclosure of which is incorporated by reference herein in its entirety.

### TECHNICAL FIELD

The present inventive concept relates to a semiconductor device, and more particularly, to a semiconductor device including a multi-bridge channel field effect transistor (MBCFET™).

### DISCUSSION OF THE RELATED ART

As one of the scaling techniques for increasing a density of a semiconductor device, a multi-gate transistor for forming a silicon body of a fin or nano-wire shape on a substrate and forming a gate on a surface of the silicon body has been under development.

Since this multi-gate transistor uses a three-dimensional channel, the multi-gate transistor may be scaled down. In addition, even though a gate length of the multi-gate transistor is not increased, a current control capability may be improved. Further, a short channel effect (SCE) in which a potential of a channel region is affected by a drain voltage may be suppressed effectively.

### SUMMARY

Aspects of the present inventive concept provide a semiconductor device that increases a process margin by forming a power rail via inside a gate cut, and prevents a short-circuit from occurring between the power rail via and a plurality of nanosheets and a source/drain region.

According to an embodiment of the present inventive concept, a semiconductor device includes: a base substrate; a first interlayer insulating layer disposed on the base substrate; a power rail disposed inside the first interlayer insulating layer; an active pattern extended in a first horizontal direction and disposed on the first interlayer insulating layer; a gate electrode extended in a second horizontal direction different from the first horizontal direction and disposed on the active pattern; a gate cut extended in the first horizontal direction and disposed on the power rail, wherein the gate cut separates the gate electrode; and a power rail via disposed inside the gate cut, wherein the power rail via is overlapped by the power rail.

According to an embodiment of the present inventive concept, a semiconductor device includes: a base substrate; a power rail extended in a first horizontal direction and disposed on the base substrate; a gate electrode extended in a second horizontal direction different from the first horizontal direction and disposed on the power rail; a gate cut extended in the first horizontal direction and disposed on the power rail, wherein the gate cut separates the gate electrode, and is in contact with the power rail; a power rail via disposed inside the gate cut, and in contact with the power rail; a source/drain region disposed on at least one side of the gate electrode; and a source/drain contact disposed on the source/drain region, wherein the source/drain contact is in contact with a sidewall of the power rail via, wherein a width in the first horizontal direction of the gate cut is greater than a width in the first horizontal direction of the power rail via, and a width in the second horizontal direction of the gate cut is greater than a width in the second horizontal direction of the power rail via.

According to an embodiment of the present inventive concept, a semiconductor device includes: a base substrate; a first interlayer insulating layer disposed on the base substrate; a power rail extended in a first horizontal direction inside the first interlayer insulating layer; a second interlayer insulating layer disposed on the first interlayer insulating layer; an active pattern extended in the first horizontal direction and disposed on the second interlayer insulating layer; a plurality of nanosheets stacked on each other and spaced apart from each other in a vertical direction on the active pattern; a field insulating layer at least partially surrounding a sidewall of the active pattern on the second interlayer insulating layer; a gate electrode extended in a second horizontal direction different from the first horizontal direction and disposed on the active pattern, wherein the gate electrode at least partially surrounds the plurality of nanosheets; a source/drain region disposed on at least one side of the gate electrode; a gate cut extended in the first horizontal direction and disposed on the power rail, wherein the gate cut passes through the second interlayer insulating layer and the field insulating layer in the vertical direction, wherein the gate cut separates the gate electrode, and is in contact with the power rail; a power rail via disposed inside the gate cut, and in contact with the power rail; and a source/drain contact connected to the source/drain region, and in contact with a sidewall of the power rail via, wherein an upper surface of the source/drain contact is coplanar with an upper surface of the power rail via, and wherein the power rail via includes: a power rail via barrier layer disposed along a sidewall of a power rail via trench formed inside the gate cut, and in contact with the gate cut; and a power rail via filling layer filling the power rail via trench and disposed on the power rail via barrier layer, wherein the power rail via filling layer is in contact with the power rail.

### BRIEF DESCRIPTION OF THE DRAWINGS

The above and features of the present inventive concept will become more apparent by describing in detail embodiments thereof with reference to the attached drawings, in which:

FIG. 1 is a schematic layout view illustrating a semiconductor device according to an embodiment of the present inventive concept;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIGS. 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, and 48 are views illustrating intermediate steps to describe a method of manufacturing a semiconductor device according to an embodiment of the present inventive concept;

FIGS. 49, 50 and 51 are cross-sectional views illustrating a semiconductor device according to an embodiment of the present inventive concept;

FIGS. 52, 53, 54 and 55 are cross-sectional views illustrating a semiconductor device according to an embodiment of the present inventive concept;

FIGS. 56, 57 58 are cross-sectional views illustrating a semiconductor device according to an embodiment of the present inventive concept;

FIGS. 59, 60, 61, and 62 are cross-sectional views illustrating a semiconductor device according to an embodiment of the present inventive concept;

FIG. 63 is a schematic layout view illustrating a semiconductor device according to an embodiment of the present inventive concept;

FIG. 64 is a cross-sectional view taken along line E-E′ of FIG. 63;

FIGS. 65 and 66 are views illustrating intermediate steps to describe a method of manufacturing a semiconductor device shown in FIGS. 63 and 64;

FIG. 67 is a cross-sectional view illustrating a semiconductor device according to an embodiment of the present inventive concept;

FIG. 68 is a schematic layout view illustrating a semiconductor device according to an embodiment of the present inventive concept; and

FIG. 69 is a cross-sectional view taken along line F-F′ of FIG. 68.

### DETAILED DESCRIPTION OF THE EMBODIMENTS

As shown, a semiconductor device according to an embodiment of the present inventive concept includes a multi-bridge channel field effect transistor (MBCFET™) including a nanosheet and a fin-type transistor (FinFET) including a channel region of a fin-type pattern shape by way of example, but the present inventive concept is not limited thereto.

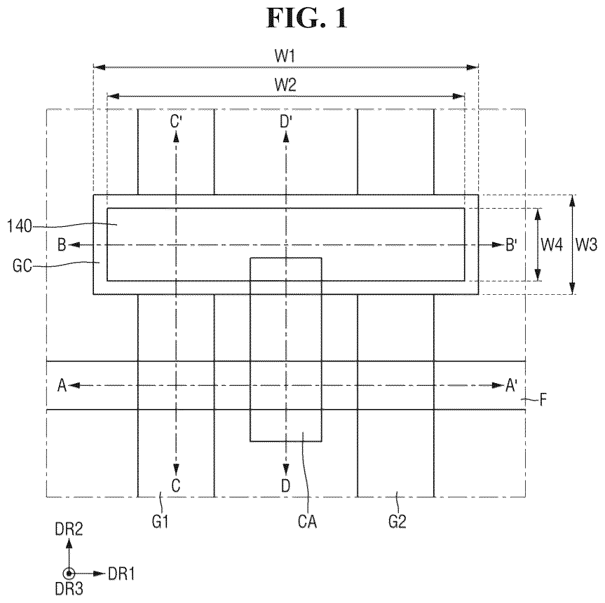

Hereinafter, a semiconductor device according to an embodiment of the present inventive concept will be described with reference to FIGS. 1 to 5.

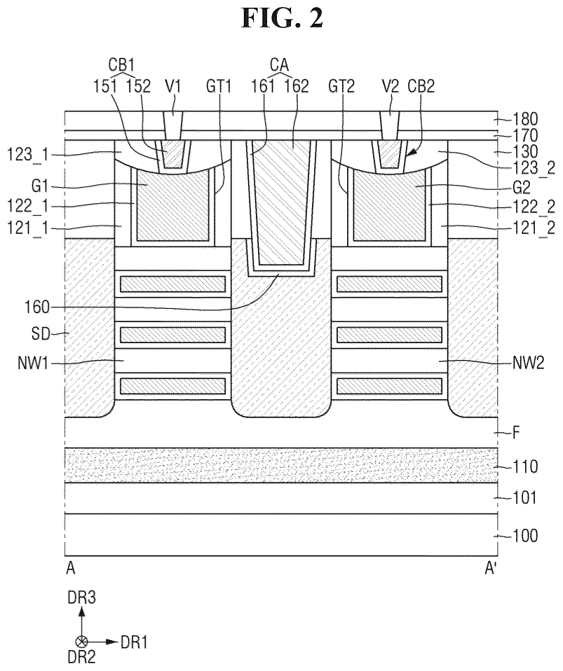

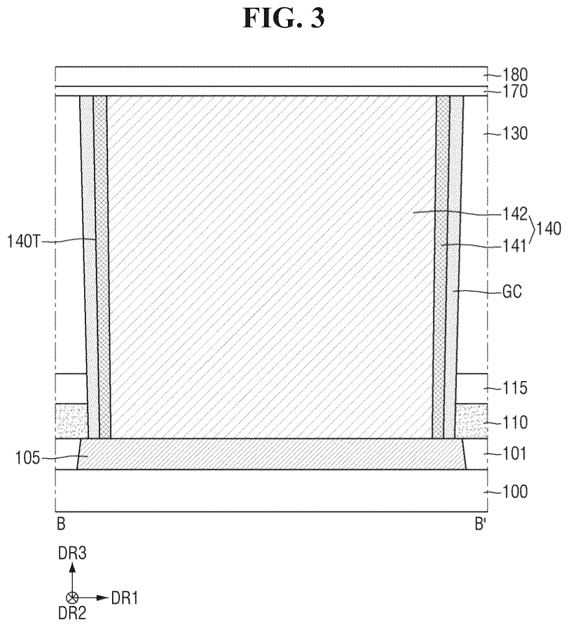

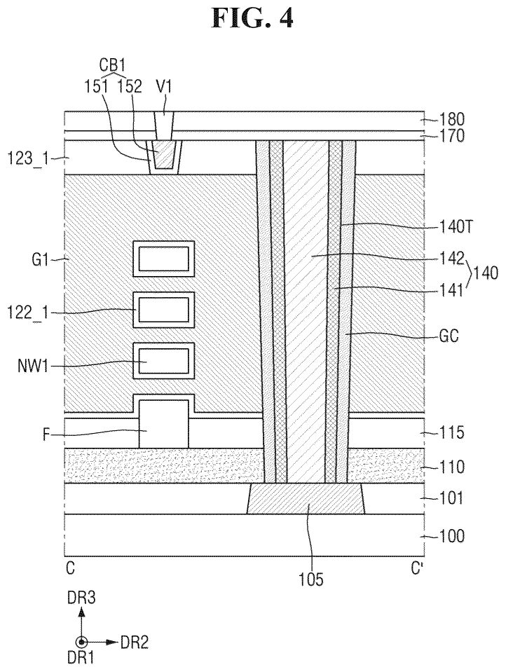

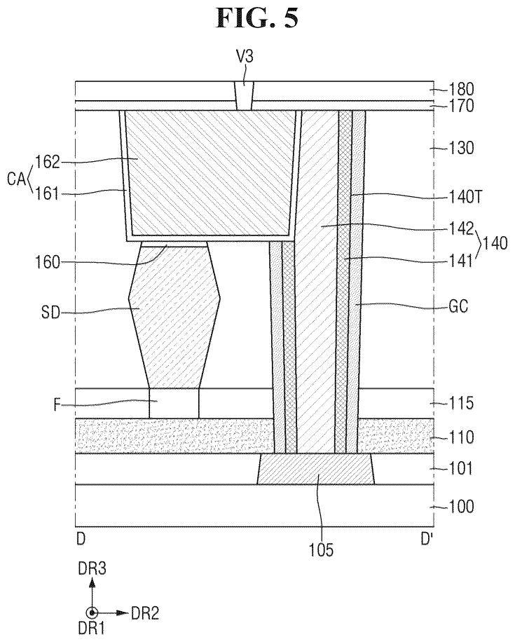

FIG. 1 is a schematic layout view illustrating a semiconductor device according to an embodiment of the present inventive concept. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1.

Referring to FIGS. 1 to 5, a semiconductor device according to an embodiment of the present inventive concept includes a base substrate 100, a first interlayer insulating layer 101, a power rail 105, a second interlayer insulating layer 110, an active pattern F, a field insulating layer 115, a plurality of first and second nanosheets NW1 and NW2, first and second gate electrodes G1 and G2, first and second gate spacers 121_1 and 121_2, first and second gate insulating layers 122_1 and 122_2, first and second capping patterns 123_1 and 123_2, a gate cut GC, a source/drain region SD, a third interlayer insulating layer 130, a power rail via 140, first and second gate contacts CB1 and CB2, a source/drain contact CA, a silicide layer 160, an etch stop layer 170, a fourth interlayer insulating layer 180, and first to third vias V1, V2 and V3.

The base substrate 100 may be, for example, a silicon substrate, but the present inventive concept is not limited thereto. For example, the base substrate 100 may include an insulating layer and a plurality of lines disposed inside the insulating layer.

The first interlayer insulating layer 101 may be disposed on the base substrate 100. The first interlayer insulating layer 101 may include, for example, at least one of a silicon oxide, a silicon nitride, a silicon oxynitride, or a low dielectric constant material. For example, the low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or their combination, but the present inventive concept is not limited thereto.

The power rail 105 may be disposed inside the first interlayer insulating layer 101. For example, the power rail 105 may be extended in a first horizontal direction DR1, but the present inventive concept is not limited thereto. The power rail 105 may include a conductive material.

For example, a width of the power rail 105 in the first horizontal direction DR1 may be increased as the power rail 105 becomes adjacent to an upper surface of the base substrate 100. In addition, a width of the power rail 105 in a second horizontal direction DR2 may be increased as the power rail 105 becomes adjacent to the upper surface of the base substrate 100. In this case, the second horizontal direction DR2 may be a direction different from the first horizontal direction DR1. Hereinafter, a vertical direction DR3 may be a direction substantially perpendicular to each of the first and second horizontal directions DR1 and DR2.

The second interlayer insulating layer 110 may be disposed on the first interlayer insulating layer 101. The second interlayer insulating layer 110 may cover an upper surface of the power rail 105. For example, the second interlayer insulating layer 110 may include the same material as that of the first interlayer insulating layer 101, but the present inventive concept is not limited thereto. The second interlayer insulating layer 110 may include, for example, at least one of a silicon oxide, a silicon nitride, a silicon oxynitride, or a low dielectric constant material.

The active pattern F may be extended in the first horizontal direction DR1 on the second interlayer insulating layer 110. The active pattern F may be protruded from an upper surface of the second interlayer insulating layer 110 in the vertical direction DR3. The active pattern F may include, for example, silicon or germanium, which is an elemental semiconductor material. In addition, the active pattern F may include a compound semiconductor, and may include, for example, a group IV-IV compound semiconductor or a group III-V compound semiconductor.

The field insulating layer 115 may be disposed on the second interlayer insulating layer 110. The field insulating layer 115 may surround a sidewall of the active pattern F. The active pattern F may be protruded in the vertical direction DR3 rather than an upper surface of the field insulating layer 115, but the present inventive concept is not limited thereto. The field insulating layer 115 may include, for example, an oxide layer, a nitride layer, an oxynitride layer, or their combination layer.

The plurality of first nanosheets NW1 may be disposed on the active pattern F. The plurality of first nanosheets NW1 may include a plurality of nanosheets stacked on each other to be spaced apart from each other in the vertical direction DR3. The plurality of first nanosheets NW1 may be disposed at a portion where the active pattern F and the first gate electrode G1 cross each other. The plurality of second nanosheets NW2 may be disposed on the active pattern F. The plurality of second nanosheets NW2 may be spaced apart from the plurality of first nanosheets NW1 in the first horizontal direction DR1. The plurality of second nanosheets NW2 may include a plurality of nanosheets stacked on each other to be spaced apart from each other in the vertical direction DR3. The plurality of second nanosheets NW2 may be disposed at a portion where the active pattern F and the second gate electrode G2 cross each other. Each of the plurality of first and second nanosheets NW1 and NW2 may include, for example, silicon (Si).

In FIGS. 2 and 4, each of the plurality of first and second nanosheets NW1 and NW2 are shown to include three nanosheets stacked on each other to be spaced apart from one another in the vertical direction DR3, but this is for convenience of description, and the present inventive concept is not limited thereto. In an embodiment of the present inventive concept, each of the plurality of first and second nanosheets NW1 and NW2 may include four or more nanosheets stacked on each other to be spaced apart from each other in the vertical direction DR3.

The first gate spacer 121_1 may be extended in the second horizontal direction DR2 on the uppermost nanosheet of the plurality of first nanosheets NW1 and the field insulating layer 115. The first gate spacer 121_1 may include two spacers spaced apart from each other in the first horizontal direction DR1. A first gate trench GT1 may be provided between the two spacers of the first gate spacer 121_1.

The second gate spacer 121_2 may be spaced apart from the first gate spacer 121_1 in the first horizontal direction DR1. The second gate spacer 121_2 may be extended in the second horizontal direction DR2 on the uppermost nanosheet of the plurality of second nanosheets NW2 and the field insulating layer 115. The second gate spacer 121_2 may include two spacers spaced apart from each other in the first horizontal direction DR1. A second gate trench GT2 may be provided between the two spacers of the second gate spacer 121_2.

Each of the first and second gate spacers 121_1 and 121_2 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or their combination.

The first gate electrode G1 may be extended in the second horizontal direction DR2 on the active pattern F and the field insulating layer 115. The first gate electrode G1 may be disposed inside the first gate trench GT1. In addition, the first gate electrode G1 may at least partially surround the plurality of first nanosheets NW1. The second gate electrode G2 may be extended in the second horizontal direction DR2 on the active pattern F and the field insulating layer 115. The second gate electrode G2 may be spaced apart from the first gate electrode G1 in the first horizontal direction DR1. The second gate electrode G2 may be disposed inside the second gate trench GT2. The second gate electrode G2 may at least partially surround the plurality of second nanosheets NW2.

Each of the first and second gate electrodes G1 and G2 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. Each of the first and second gate electrodes G1 and G2 may include a conductive metal oxide, a conductive metal oxynitride, and the like, and may include oxidized forms of the aforementioned materials.

The source/drain region SD may be disposed on at least one side of each of the first and second gate electrodes G1 and G2 on the active pattern F. For example, the source/drain region SD may be disposed on both sides of each of the first and second gate electrodes G1 and G2 on the active pattern F. The source/drain region SD may be in contact with each of the plurality of first and second nanosheets NW1 and NW2.

The first gate insulating layer 122_1 may be disposed along a sidewall and a bottom surface of the first gate trench GT1. For example, the first gate insulating layer 122_1 may be disposed between the first gate electrode G1 and the first gate spacer 121_1 in the first gate trench GT1. The first gate insulating layer 1221 may be disposed between the first gate electrode G1 and the field insulating layer 115. The first gate insulating layer 122_1 may be disposed between the first gate electrode G1 and the plurality of first nanosheets NW1. The first gate insulating layer 122_1 may be disposed between the first gate electrode G1 and the active pattern F. The first gate insulating layer 122_1 may be disposed between the first gate electrode G1 and the source/drain region SD.

The second gate insulating layer 122_2 may be disposed along a sidewall and a bottom surface of the second gate trench GT2. For example, the second gate insulating layer 122_2 may be disposed between the second gate electrode G2 and the second gate spacer 121_2 in the second gate trench GT2. The second gate insulating layer 122_2 may be disposed between the second gate electrode G2 and the field insulating layer 115. The second gate insulating layer 122_2 may be disposed between the second gate electrode G2 and the plurality of second nanosheets NW2. The second gate insulating layer 122_2 may be disposed between the second gate electrode G2 and the active pattern F. The second gate insulating layer 122_2 may be disposed between the second gate electrode G2 and the source/drain region SD.

Each of the first and second gate insulating layers 122_1 and 122_2 may include at least one of, for example, silicon oxide, silicon oxynitride, silicon nitride, and/or a high dielectric constant material having a dielectric constant greater than that of the silicon oxide. The high dielectric constant material may include one or more of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to an embodiment of the present inventive concept may include a negative capacitance (NC) FET based on a negative capacitor. For example, each of the first and second gate insulating layers 122_1 and 122_2 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. In addition, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer connected in series may be increased. Based on the total capacitance value that is increased, a transistor having a ferroelectric material layer may have a subthreshold swing (SS) less than about 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, and/or lead zirconium titanium oxide. In this case, for example, hafnium zirconium oxide may be a material doped with zirconium (Zr) in hafnium oxide. For another example, hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of about 3 at % to about 8 at % (atomic %). In this case, a ratio of the dopant may be a ratio of aluminum to a sum of hafnium and aluminum.

When the dopant is silicon (Si), the ferroelectric material layer may include silicon of about 2 at/o to about 10 at %. When the dopant is yttrium (Y), the ferroelectric material layer may include yttrium of about 2 at % to about 10 at %. When the dopant is gadolinium (Gd), the ferroelectric material layer may include gadolinium of about 1 at % to about 7 at %. When the dopant is zirconium (Zr), the ferroelectric material layer may include zirconium of 50 at % to 80 at %.

The paraelectric material layer may have paraelectric characteristics. The paraelectric material layer may include, for example, at least one of silicon oxide or metal oxide having a high dielectric constant. The metal oxide included in the paraelectric material layer may include, but is not limited to, at least one of hafnium oxide, zirconium oxide, and/or aluminum oxide.

The ferroelectric material layer and the paraelectric material layer may include the same material as each other. Although the ferroelectric material layer has ferroelectric characteristics, the paraelectric material layer might not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, about 0.5 nm to about 10 nm, but the present inventive concept is not limited thereto. Since a threshold thickness indicating ferroelectric characteristics may be varied depending on each ferroelectric material, the thickness of the ferroelectric material layer may be varied depending on the ferroelectric material.

For example, each of the first and second gate insulating layers 122_1 and 122_2 may include one ferroelectric material layer. For another example, each of the first and second gate insulating layers 122_1 and 122_2 may include a plurality of ferroelectric material layers spaced apart from each other. Each of the first and second gate insulating layers 122_1 and 122_2 may have a stacked layer structure in which a plurality of ferroelectric material layers and a plurality of paraelectric material layers are alternately stacked on each other.

The first capping pattern 123_1 may be extended in the second horizontal direction DR2_1 on the first gate electrode G1 and the first gate spacer 121_1. For example, the first capping pattern 123_1 may be in contact with an upper surface of the first gate spacer 121_1, but the present inventive concept is not limited thereto. In an embodiment of the present inventive concept, the first capping pattern 123_1 may be disposed between the first gate spacers 121_1. In this case, an upper surface of the first capping pattern 123_1 may be formed on the same plane as that of the first gate spacer 121_1.

The second capping pattern 123_2 may be extended in the second horizontal direction DR2 on the second gate electrode G2 and the second gate spacer 121_2. For example, the second capping pattern 123_2 may be in contact with an upper surface of the second gate spacer 121_2, but the present inventive concept is not limited thereto. In an embodiment of the present inventive concept, the second capping pattern 123_2 may be disposed between the second gate spacers 121_2. In this case, the upper surface of the second capping pattern 123_2 may be formed on the same plane as that of the second gate spacer 121_2.

Each of the first and second capping patterns 123_1 and 123_2 may include, for example, at least one of silicon nitride (SiN), silicon oxynitride (SiON), silicon oxide (SiO₂), silicon carbonitride (SiCN), silicon oxycarbonitride (SiOCN), or a combination thereof.

The third interlayer insulating layer 130 may be disposed on the field insulating layer 115. The third interlayer insulating layer 130 may cover the source/drain regions SD. The third interlayer insulating layer 130 may cover a sidewall of each of the first and second gate spacers 121_1 and 121_2. For example, the third interlayer insulating layer 130 may at least partially surround a sidewall of each of the first and second gate spacers 121_1 and 121_2. For example, an upper surface of the third interlayer insulating layer 130 may be coplanar with the upper surface of each of the first and second capping patterns 123_1 and 123_2, but the present inventive concept is not limited thereto.

The third interlayer insulating layer 130 may include, for example, at least one of silicon oxide, silicon nitride, silicon oxycarbide, silicon oxynitride, silicon oxycarbonitride, and/or a low dielectric constant material.

The gate cut GC may be extended in the first horizontal direction DR1 on the power rail 105. For example, the gate cut GC may be spaced apart from the active pattern F in the second horizontal direction DR2. The gate cut GC may cross the first gate electrode G1. The gate cut GC may separate or divide the first gate electrode G1 in the second horizontal direction DR2. The first gate electrode G1 may be completely separated by the gate cut GC. The gate cut GC may cross the second gate electrode G2. The gate cut GC may separate the second gate electrode G2 in the second horizontal direction DR2. The second gate electrode G2 may be completely separated by the gate cut GC.

The gate cut GC may be extended to the power rail 105 by passing through the first capping pattern 123_1, the first gate electrode G1, the first gate insulating layer 122_1, the field insulating layer 115 and the second interlayer insulating layer 110 in the vertical direction DR3 at a portion crossing the first gate electrode G1. The gate cut GC may be extended to the power rail 105 by passing through the second capping pattern 123_2, the second gate electrode G2, the second gate insulating layer 122_2, the field insulating layer 115 and the second interlayer insulating layer 110 in the vertical direction DR3 at a portion crossing the second gate electrode G2. The gate cut GC may be extended to the power rail 105 by passing through the third interlayer insulating layer 130, the field insulating layer 115 and the second interlayer insulating layer 110 in the vertical direction DR3 at a portion that does not cross each of the first and second gate electrodes G1 and G2. For example, the gate cut GC may be in contact with the power rail 105.

For example, an upper surface of the gate cut GC may be coplanar with each of the upper surface of the first capping pattern 123_1, the upper surface of the second capping pattern 123_2, and the upper surface of the third interlayer insulating layer 130. A width of the gate cut GC in the first horizontal direction DR1 may be reduced as the gate cut GC approaches the power rail 105. In addition, a width of the gate cut GC in the second horizontal direction DR2 may be reduced as the gate cut GC approaches the power rail 105. The gate cut GC may include, for example, at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), or a combination thereof.

The power rail via 140 may be disposed on the power rail 105. The power rail via 140 may be extended in the first horizontal direction DR1. The power rail via 140 may be disposed inside a power rail via trench 140T formed inside the gate cut GC. A sidewall of the power rail via 140 may be at least partially surrounded by the gate cut GC. At least a portion of the power rail via 140 may overlap the first gate electrode G1 in the second horizontal direction DR2. In addition, at least a portion of the power rail via 140 may overlap the second gate electrode G2 in the second horizontal direction DR2. For example, the sidewall of the power rail via 140 may be in contact with the gate cut GC. A lower surface of the power rail via 140 may be in contact with the power rail 105.

For example, an upper surface of the power rail via 140 may be coplanar with each of the upper surface of the first capping pattern 123_1, the upper surface of the second capping pattern 123_2, the upper surface of the third interlayer insulating layer 130, and the upper surface of the gate cut GC. A width of the power rail via 140 in the first horizontal direction DR1 may be reduced as the power rail via 140 approaches the power rail 105. Further, a width of the power rail via 140 in the second horizontal direction DR2 may be reduced as the power rail via 140 approaches the power rail 105.

For example, a width W2 of the power rail via 140 in the first horizontal direction DR1 may be smaller than a width W1 of the gate cut GC in the first horizontal direction DR1. For example, a width W4 of the power rail via 140 in the second horizontal direction DR2 may be smaller than a width W3 of the gate cut GC in the second horizontal direction DR2.

The power rail via 140 may include a power rail via barrier layer 141 and a power rail via filling layer 142. The power rail via barrier layer 141 may be disposed along a sidewall of the power rail via trench 140T. The power rail via barrier layer 141 may overlap with the gate cut GC. For example, the power rail via barrier layer 141 may be in contact with the gate cut GC. The power rail via barrier layer 141 may be in contact with the power rail 105. For example, an uppermost surface of the power rail via barrier layer 141 may be coplanar with the upper surface of the gate cut GC.

The power rail via barrier layer 141 may include an insulating material. For example, the power rail via barrier layer 141 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), or a combination thereof.

The power rail via filling layer 142 may fill a remaining space of the power rail via trench 140T on the power rail via barrier layer 141. The power rail via filling layer 142 may be disposed on the power rail 105. For example, the power rail via filling layer 142 may be in contact with the power rail 105. For example, the power rail via filling layer 142 may be coplanar with the upper surface of the gate cut GC. The power rail via filling layer 142 may include a conductive material.

The first gate contact CB1 may be connected to the first gate electrode G1 by passing through the first capping pattern 123_1 in the vertical direction DR3. For example, an upper surface of the first gate contact CB1 may be coplanar with an upper surface of the first capping pattern 123_1. The second gate contact CB2 may be connected to the second gate electrode G2 by passing through the second capping pattern 123_2 in the vertical direction DR3. For example, an upper surface of the second gate contact CB2 may be coplanar with an upper surface of the second capping pattern 123_2.

Each of the first and second gate contacts CB1 and CB2 may include a gate contact barrier layer 151 and a gate contact filling layer 152. The gate contact barrier layer 151 may form a sidewall and a bottom surface of each of the first and second gate contacts CB1 and CB2. The gate contact barrier layer 151 may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), and/or rhodium (Rh). The gate contact filling layer 152 may include, for example, at least one of aluminum (Al), copper (Cu), tungsten (W), cobalt (Co), ruthenium (Ru), and/or molybdenum (Mo).

The gate contact filling layer 152 may be disposed on the gate contact barrier layer 151. The gate contact filling layer 152 may include a conductive material. The gate contact filling layer 152 may include, for example, cobalt (Co), but the present inventive concept is not limited thereto.

The source/drain contact CA may be disposed on the source/drain region SD. For example, the source/drain contact CA may be disposed on the source/drain region SD that will be disposed between the first gate electrode G1 and the second gate electrode G2. The source/drain contact CA may be extended in the second horizontal direction DR2. The source/drain contact CA may be in contact with the sidewall of the power rail via 140. For example, the source/drain contact CA may be in contact with a sidewall of the power rail via filling layer 142. The source/drain contact CA may overlap at least a portion of the gate cut GC in the vertical direction DR3. In addition, the source/drain contact CA may overlap at least a portion of the power rail via barrier layer 141 in the vertical direction DR3. An upper surface of the source/drain contact CA may be coplanar with each of the upper surface of the gate cut GC and the upper surface of the power rail via 140.

The source/drain contact CA may include a source/drain contact barrier layer 161 and a source/drain contact filling layer 162. The source/drain contact barrier layer 161 may form a sidewall and a bottom surface of the source/drain contact CA. The source/drain contact barrier layer 161 may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), and/or rhodium (Rh). The source/drain contact filling layer 162 may include, for example, at least one of aluminum (Al), copper (Cu), tungsten (W), cobalt (Co), ruthenium (Ru), and/or molybdenum (Mo).

The source/drain contact filling layer 162 may be disposed on the source/drain contact barrier layer 161. The source/drain contact filling layer 162 may include a conductive material. The source/drain contact filling layer 162 may include, for example, cobalt (Co), but the present inventive concept is not limited thereto.

The silicide layer 160 may be disposed between the source/drain region SD and the source/drain contact CA. The silicide layer 160 may be formed along a profile of a boundary surface between the source/drain region SD and the source/drain contact CA. The silicide layer 160 may include, for example, a metal silicide material.

The etch stop layer 170 may be disposed on the first and second capping patterns 123_1 and 123_2, the gate cut GC, the power rail via 140, and the third interlayer insulating layer 130. Although FIGS. 2 to 5 show that the etch stop layer 170 is formed of a single layer, the present inventive concept is not limited thereto. In an embodiment of the present inventive concept, the etch stop layer 170 may be a multi-layer structure. The etch stop layer 170 may include, for example, at least one of aluminum oxide, aluminum nitride, hafnium oxide, zirconium oxide, silicon oxide, silicon nitride, silicon oxynitride, and/or a low dielectric constant material.

The fourth interlayer insulating layer 180 may be disposed on the etch stop layer 170. The fourth interlayer insulating layer 180 may include, for example, at least one of silicon oxide, silicon nitride, silicon oxynitride, and/or a low dielectric constant material.

The first via V1 may be connected to the first gate contact CB1 by passing through the fourth interlayer insulating layer 180 and the etch stop layer 170 in the vertical direction DR3. The second via V2 may be connected to the second gate contact CB2 by passing through the fourth interlayer insulating layer 180 and the etch stop layer 170 in the vertical direction DR3. The third via V3 may be connected to the source/drain contact CA by passing through the fourth interlayer insulating layer 180 and the etch stop layer 170 in the vertical direction DR3. Although FIGS. 2 to 5 show that each of the first to third vias V1, V2 and V3 is formed of a single layer, the present inventive concept is not limited thereto. For example, each of the first to third vias V1, V2 and V3 may be formed of a multi-layer structure. Each of the first to third vias V1, V2 and V3 may include a conductive material.

Although FIG. 2 shows that an inner spacer is not disposed between each of the first and second gate electrodes G1 and G2 and the source/drain region SD, the present inventive concept is not limited thereto. In an embodiment of the present inventive concept, the inner spacer may be disposed between each of the first and second gate electrodes G1 and G2 and the source/drain regions SD.

The semiconductor device according to an embodiment of the present inventive concept may increase a process margin by forming the power rail via 140 inside the gate cut GC. In addition, the semiconductor device according to an embodiment of the present inventive concept may form the power rail via 140 inside the gate cut GC to prevent a short circuit from occurring between the power rail via 140 and the plurality of nanosheets NW1 and NW2, and the source/drain region SD.

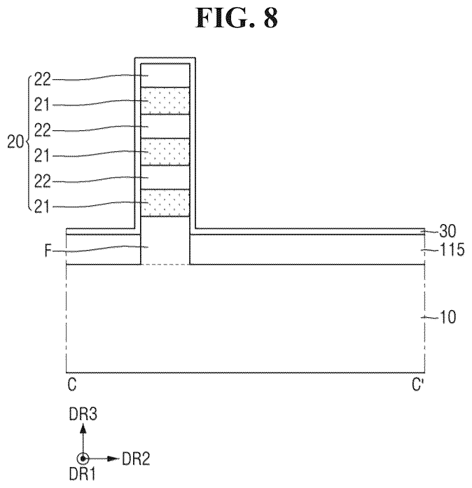

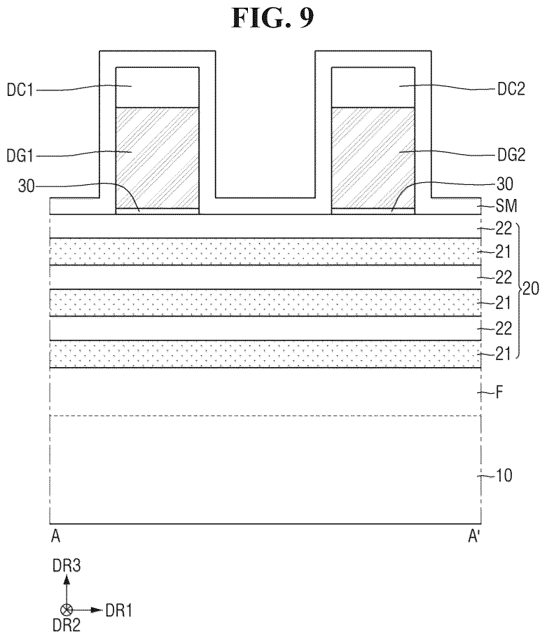

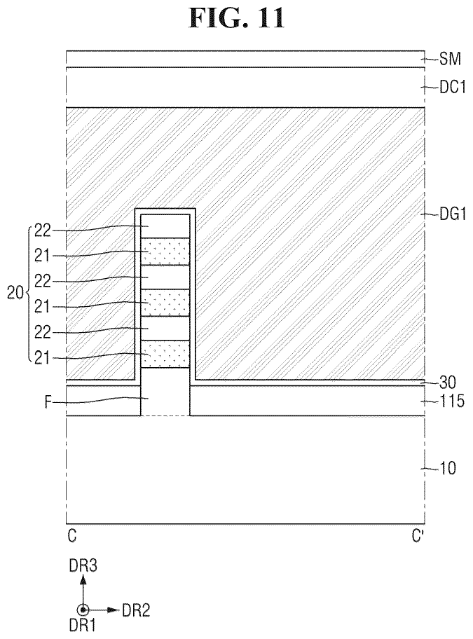

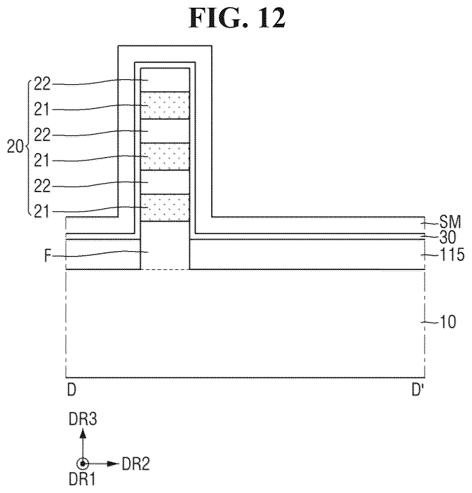

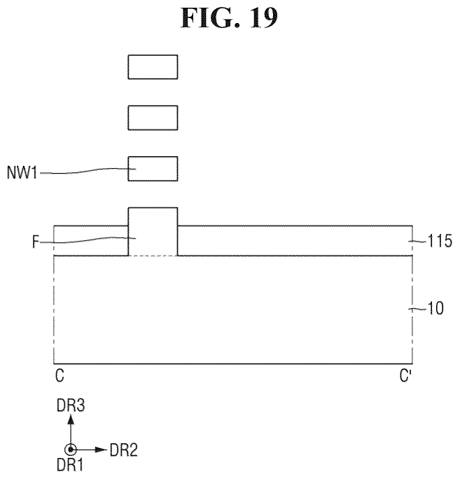

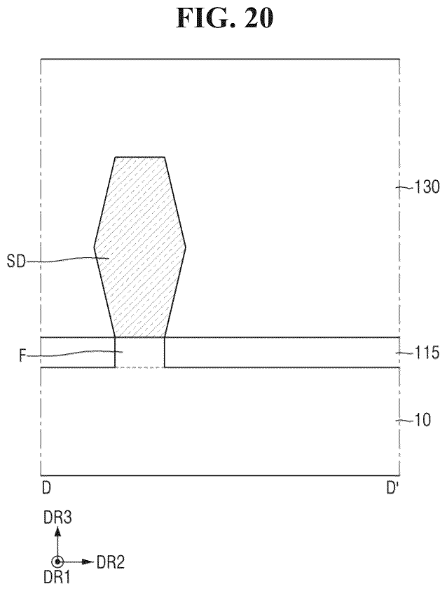

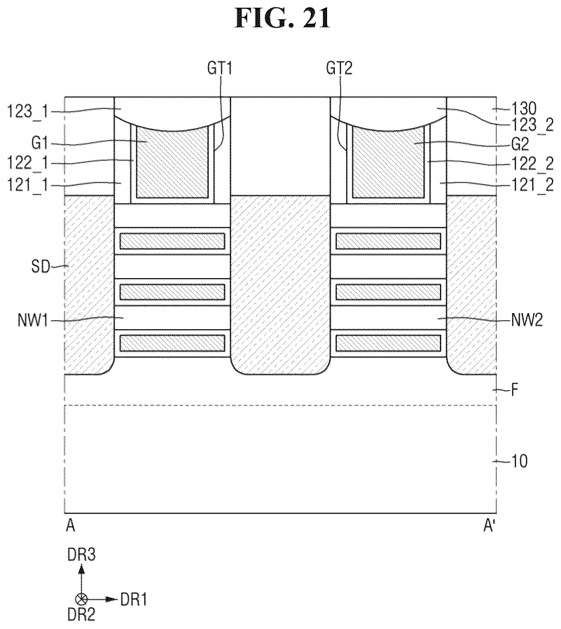

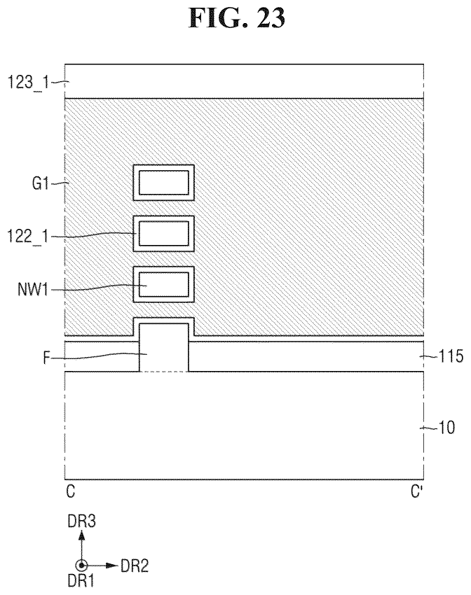

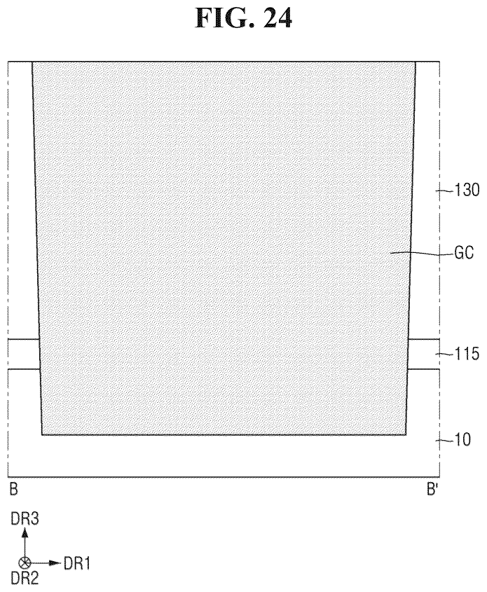

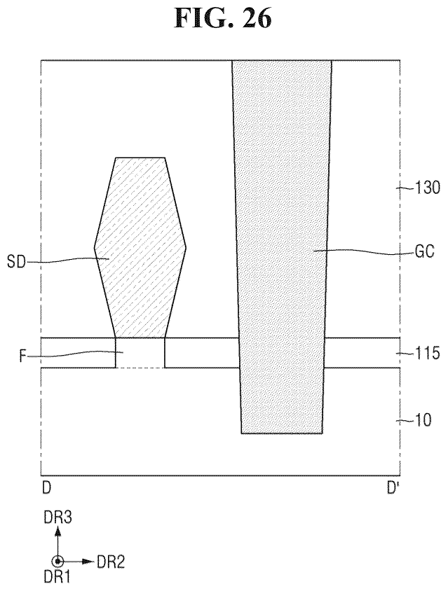

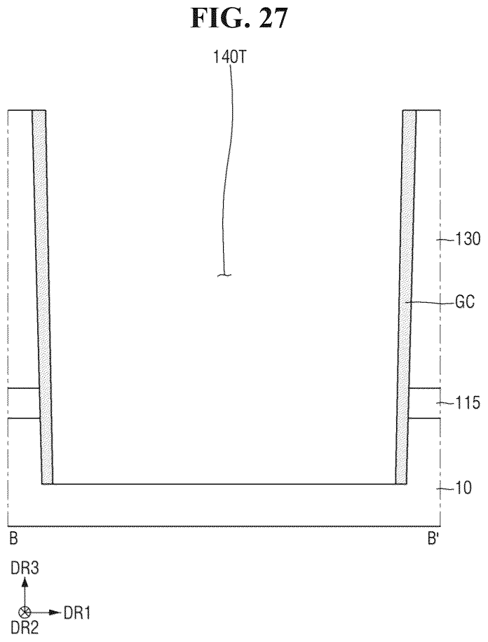

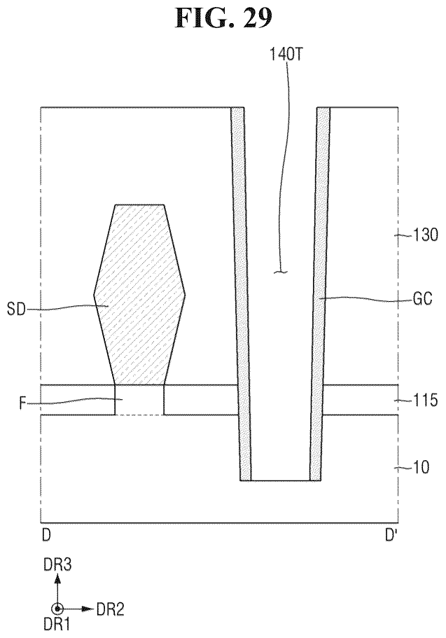

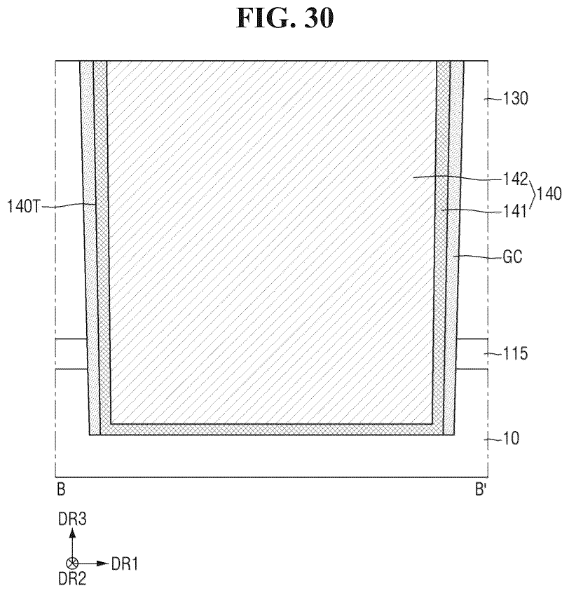

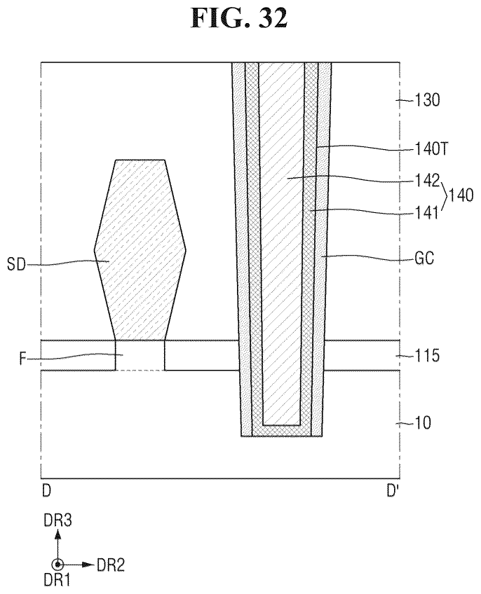

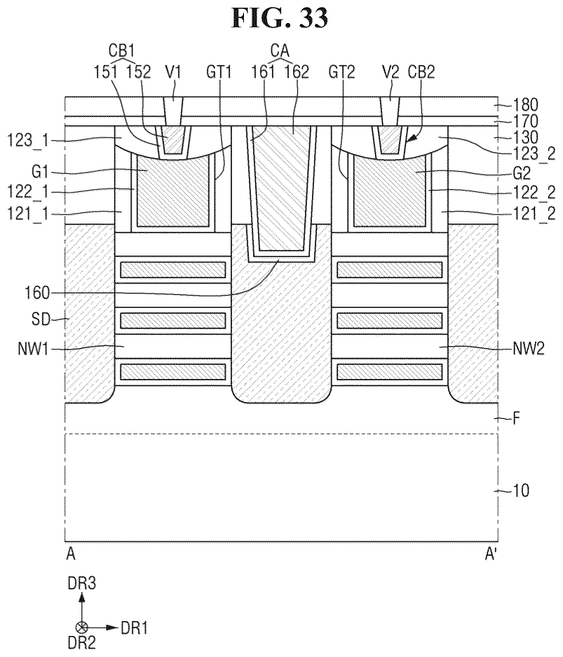

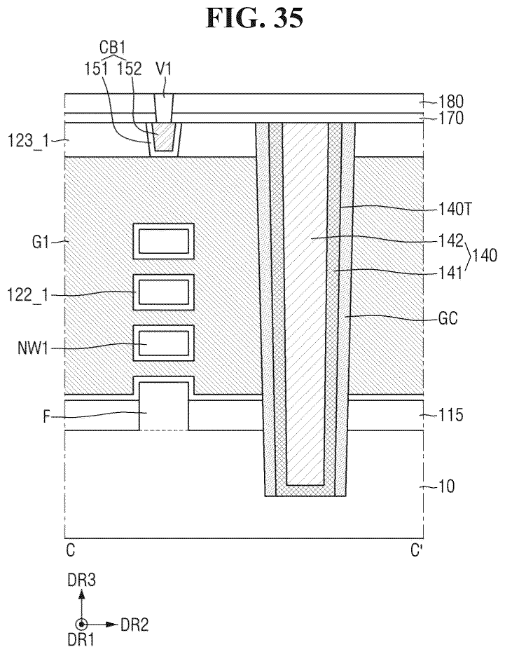

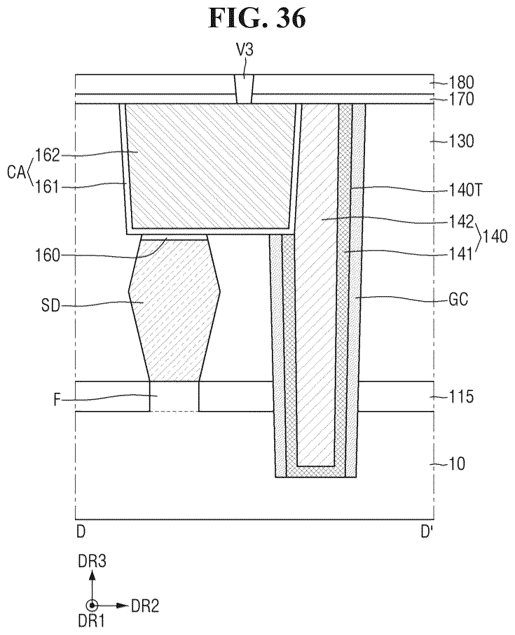

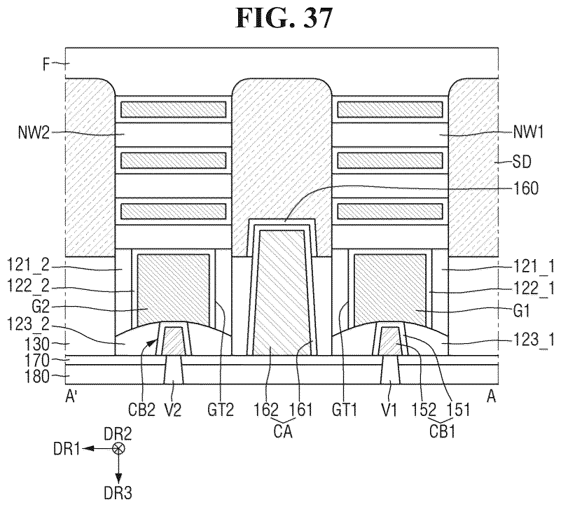

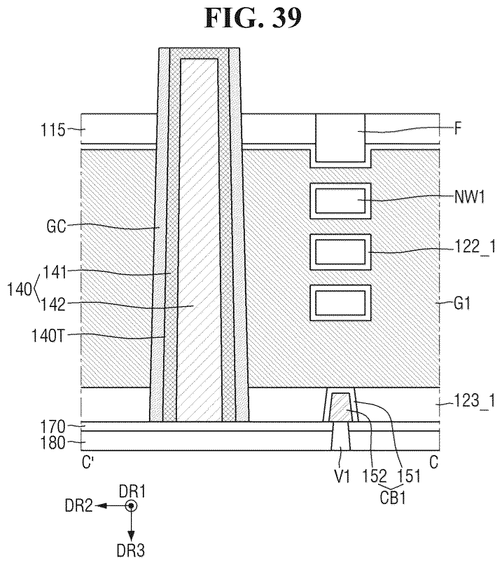

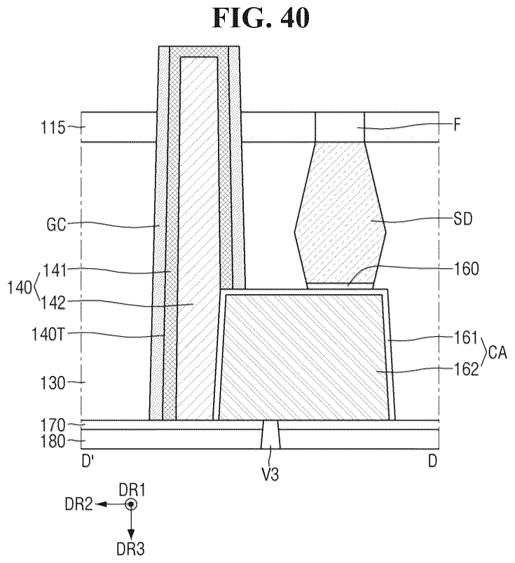

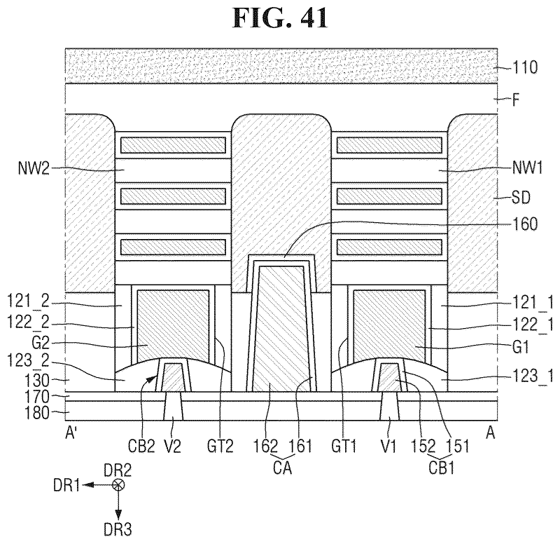

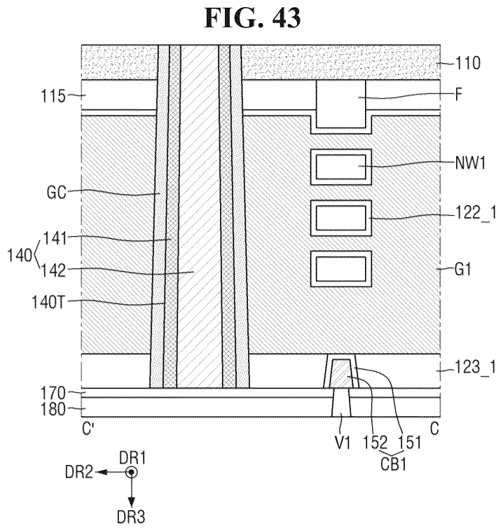

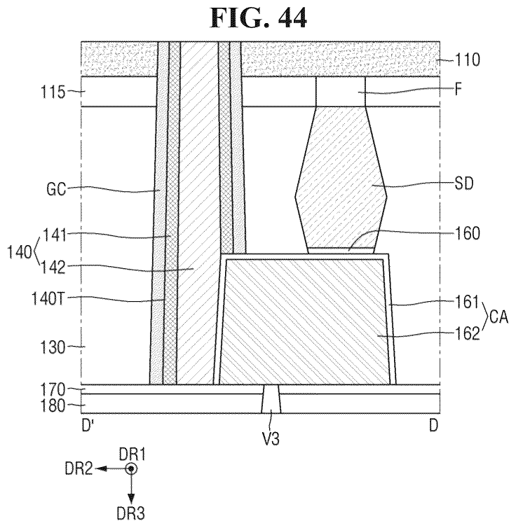

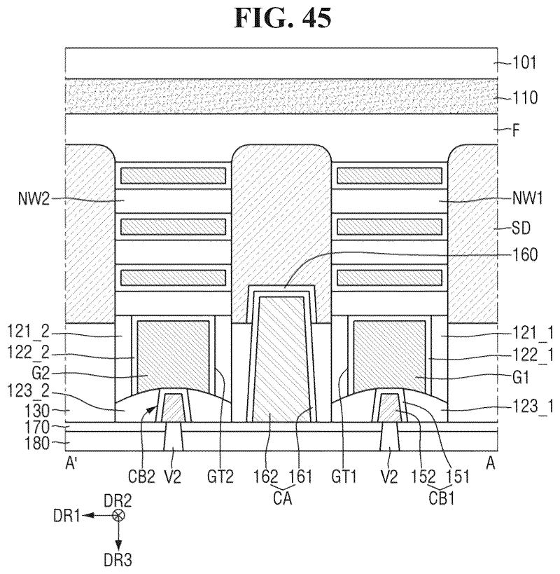

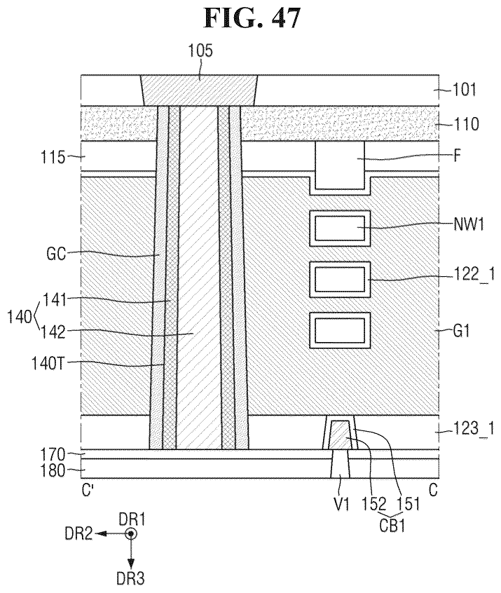

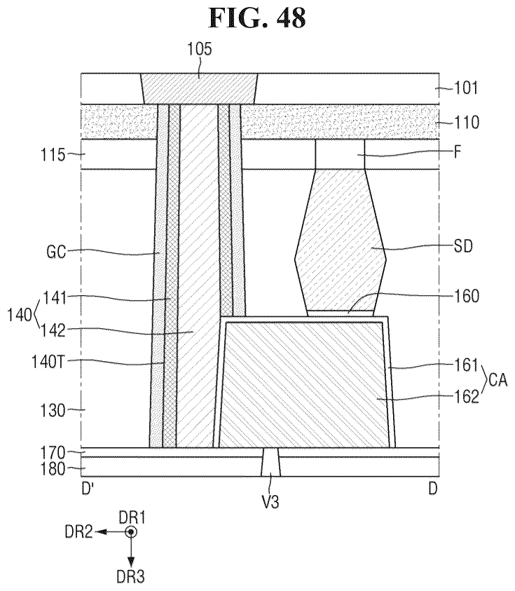

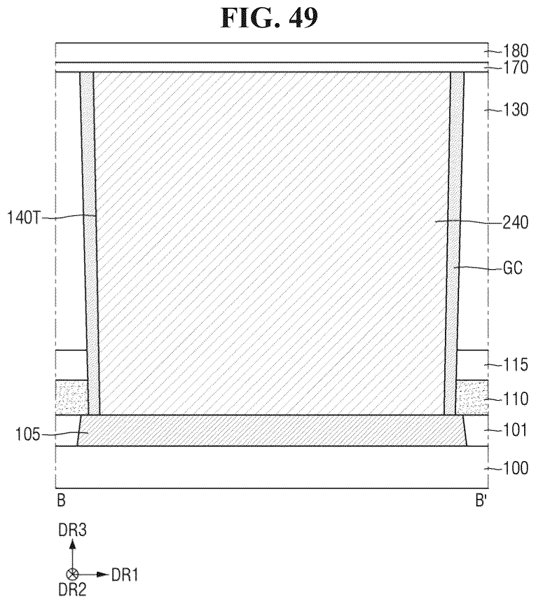

Hereinafter, a method of manufacturing a semiconductor device according to an embodiment of the present inventive concept will be described with reference to FIGS. 2 to 48.

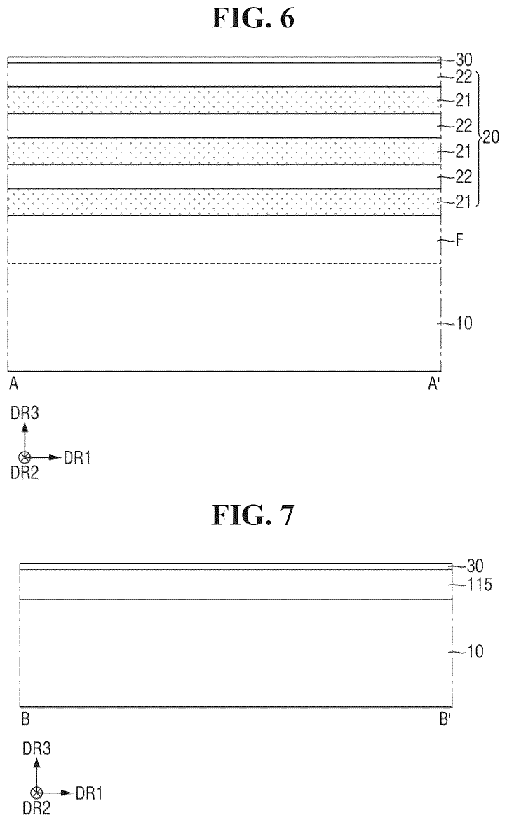

FIGS. 6 to 48 are views illustrating intermediate steps to describe a method of manufacturing a semiconductor device according to an embodiment of the present inventive concept.

Referring to FIGS. 6 to 8, a substrate 10 may be provided. The substrate 10 may be a silicon substrate or a silicon-on-insulator (SOI). In addition, the substrate 10 may include, for example, silicon germanium, silicon germanium on insulator (SGOI), antimony indium, lead telluride compounds, indium arsenide, indium phosphide, gallium arsenide and/or antimony gallium, but the present inventive concept is not limited thereto.

Subsequently, a stacked structure 20 may be formed on the substrate 10. The stacked structure 20 may include a sacrificial layer 21 and a semiconductor layer 22, which are alternately stacked on each other on the substrate 10. For example, the sacrificial layer 21 may be formed on the lowermost portion of the stacked structure 20, and the semiconductor layer 22 may be formed on the uppermost portion of the stacked structure 20, but the present inventive concept is not limited thereto. In an embodiment of the present inventive concept, the sacrificial layer 21 may be also formed on the uppermost portion of the stacked structure 20. The sacrificial layer 21 may include, for example, silicon germanium (SiGe). The semiconductor layer 22 may include, for example, silicon (Si).

Subsequently, a portion of the stacked structure 20 may be etched. A portion of the substrate 10 may be also etched while the stacked structure 20 is being etched; however, the present inventive concept is not limited thereto, and the stacked structure 20 may be etched at a different time from that of the substrate 10. Through this etching process, an active pattern F may be formed below the stacked structure 20 on the substrate 10. Subsequently, a field insulating layer 115 surrounding a sidewall of the active pattern F may be formed. For example, an upper surface of the active pattern F may be higher than that of the field insulating layer 115.

Subsequently, a pad oxide layer 30 may be formed to cover the upper surface of the field insulating layer 115, the exposed sidewall of the active pattern F, and a sidewall and an upper surface of the stacked structure 20. For example, the pad oxide layer 30 may be formed to be conformal to the surface on which it is formed. The pad oxide layer 30 may include, for example, silicon oxide (SiO₂).

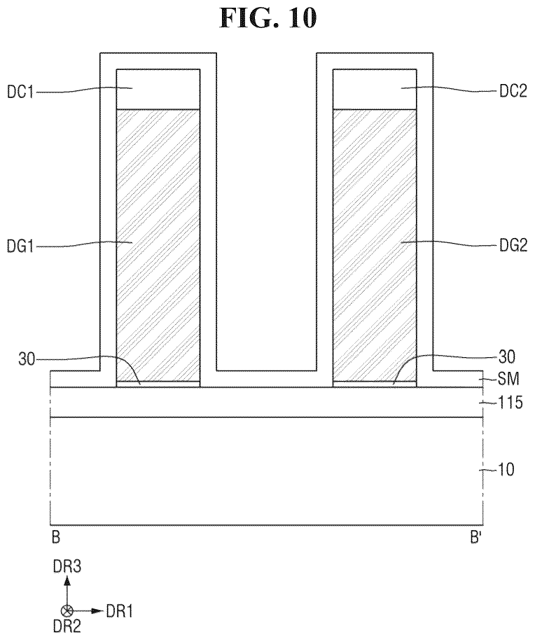

Referring to FIGS. 9 to 12, first and second dummy gates DG1 and DG2 and first and second dummy capping patterns DC1 and DC2, which are extended in the second horizontal direction DR2 on the pad oxide layer 30, may be formed on the stacked structure 20 and the field insulating layer 115. The first dummy capping pattern DC1 may be formed on the first dummy gate DG1. The second dummy capping pattern DC2 may be formed on the second dummy gate DG2. Each of the second dummy gate DG2 and the second dummy capping pattern DC2 may be spaced apart from each of the first dummy gate DG1 and the first dummy capping pattern DC1 in the first horizontal direction DR1. While the first and second dummy gates DG1 and DG2 and the first and second dummy capping patterns DC1 and DC2 are being formed, a portion of the pad oxide layer 30 that is not overlapped with each of the first and second dummy gates DG1 and DG2 in the vertical direction DR3 on the substrate 10 may be removed.

Subsequently, a spacer material layer SM may be formed to cover sidewalls of the first and second dummy gates DG1 and DG2, sidewalls and upper surfaces of the first and second dummy capping patterns DC1 and DC2, and the exposed sidewalls and upper surfaces of the stacked structure 20. The spacer material layer SM may be formed on the exposed upper surface of the field insulating layer 115. For example, the spacer material layer SM may be formed to be conformal to the surface or surfaces on which it is formed. The spacer material layer SM may include, for example, at least one of silicon nitride (SiN), silicon oxycarbonitride (SiOCN), silicon boron carbonitride (SiBCN), silicon carbonitride (SiCN), silicon oxynitride (SiON), and/or their combination.

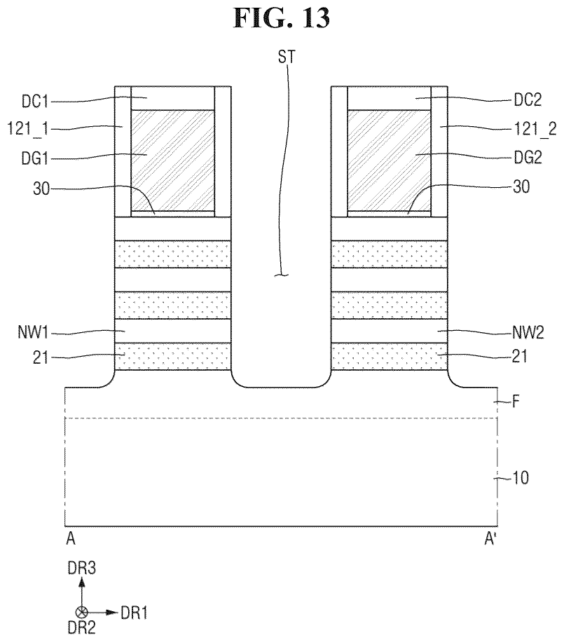

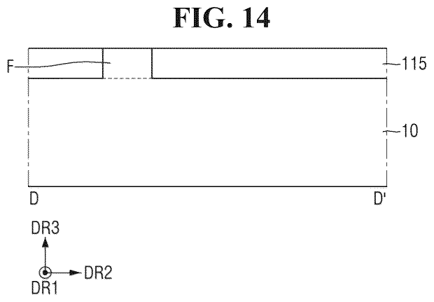

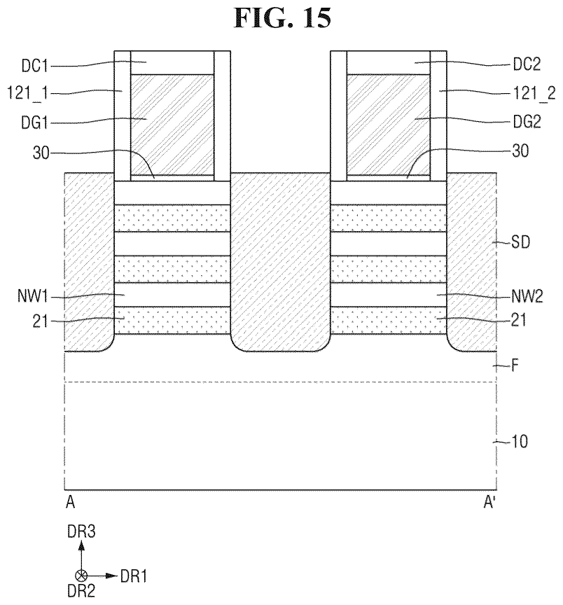

Referring to FIGS. 13 and 14, the stacked structure (20 of FIGS. 9 and 12) may be etched using the first and second dummy gates DG1 and DG2 and the first and second dummy capping patterns DC1 and DC2 as masks to form a source/drain trench ST. For example, the source/drain trench ST may be extended to the inside of the active pattern F.

While the source/drain trench ST is being formed, a portion of each of the first and second dummy capping patterns DC1 and DC2 and the spacer material layer (SM of FIGS. 9 and 12) formed on the upper surface of each of the first and second dummy capping patterns DC1 and DC2 may be removed. The spacer material layer (SM of FIG. 9) remaining on the sidewall of each of the first dummy gate DG1 and the first dummy capping pattern DC1 may be a first gate spacer 121_1. In addition, the spacer material layer (SM of FIG. 9) remaining on the sidewall of each of the second dummy gate DG2 and the second dummy capping pattern DC2 may be a second gate spacer 121_2.

After the source/drain trench ST is formed, the semiconductor layer (22 of FIG. 9) remaining below the first dummy gate DG1 may be a plurality of first nanosheets NW1. In addition, after the source/drain trench ST is formed, the semiconductor layer (22 of FIG. 9) remaining below the second dummy gate DG2 may be a plurality of second nanosheets NW2.

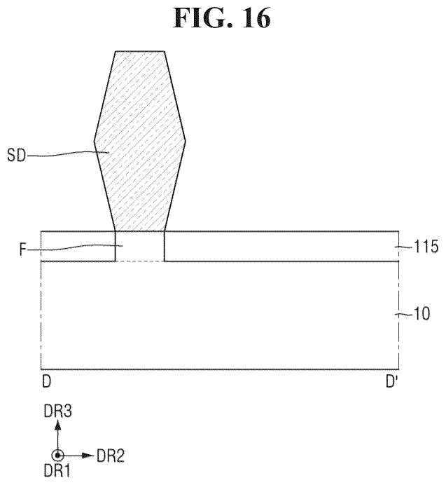

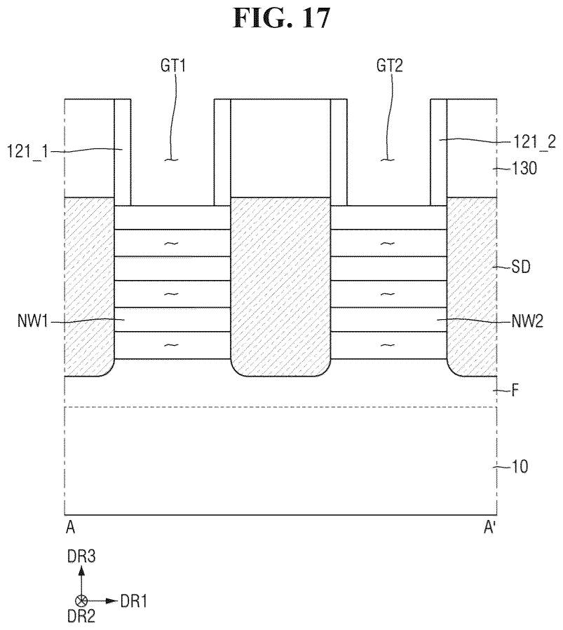

Referring to FIGS. 15 and 16, a source/drain region SD may be formed inside the source/drain trench (ST of FIG. 13). For example, the source/drain region SD may be formed to be epitaxially grown from each of the active pattern F and the plurality of first and second nanosheets NW1 and NW2.

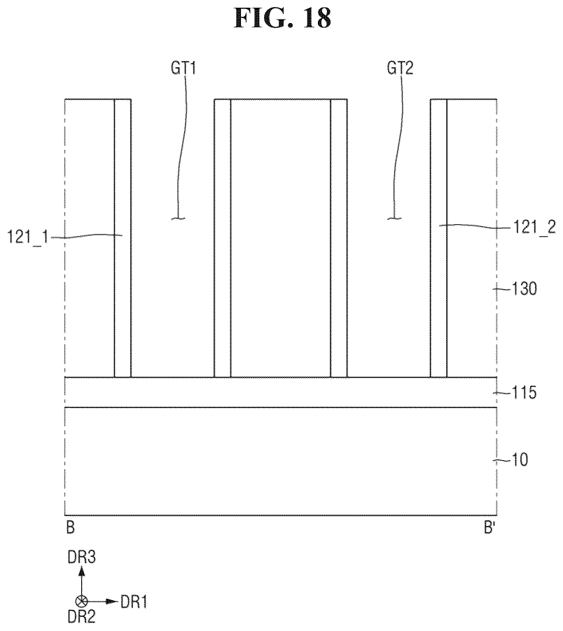

Referring to FIGS. 17 to 20, a third interlayer insulating layer 130 may be formed to cover the source/drain region SD, the first and second gate spacers 121_1 and 121_2 and the first and second dummy capping patterns (DC1 and DC2 of FIG. 15), respectively. Subsequently, an upper surface of each of the first and second dummy gates (DG1 and DG2 of FIG. 15) may be exposed through a planarization process. Subsequently, each of the first and second dummy gates (DG1 and DG2 of FIG. 15), the pad oxide layer (30 of FIG. 15) and the sacrificial layer (21 of FIG. 15) may be removed. The region between the first gate spacers 121_1 from which the first dummy gate (DG1 of FIG. 15) is removed may be a first gate trench GT1, and the region between the second gate spacers 121_2 from which the second dummy gate (DG2 of FIG. 15) is removed may be a second gate trench GT2.

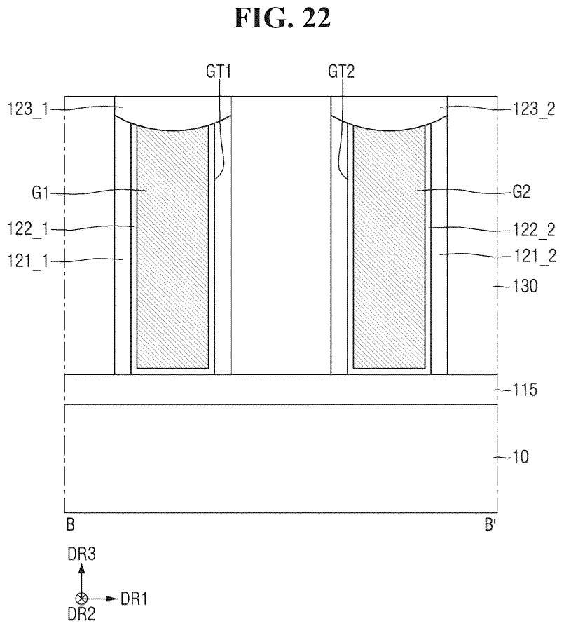

Referring to FIGS. 21 to 23, the first gate insulating layer 122_1 and the first gate electrode G1 may be sequentially formed at the region from which the first dummy gate (DG1 of FIG. 15) and the sacrificial layer (21 of FIG. 15) below the first dummy gate (DG1 of FIG. 15) are removed. In addition, the second gate insulating layer 122_2 and the second gate electrode G2 may be sequentially formed at the region from which the second dummy gate (DG2 of FIG. 15) and the sacrificial layer (21 of FIG. 15) below the second dummy gate (DG2 of FIG. 15) are removed.

Subsequently, a first capping pattern 123_1 may be formed on the first gate spacer 121_1, the first gate insulating layer 122_1 and the first gate electrode G1, respectively. In addition, a second capping pattern 123_2 may be formed on the second gate spacer 121_2, the second gate insulating layer 122_2 and the second gate electrode G2, respectively. For example, each of an upper surface of the first capping pattern 123_1 and an upper surface of the second capping pattern 123_2 may be coplanar with an upper surface of the third interlayer insulating layer 130.

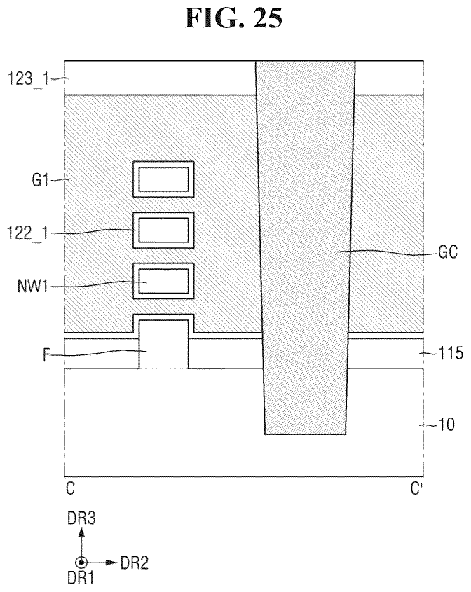

Referring to FIGS. 24 to 26, a gate cut GC extended in the first horizontal direction DR1 may be formed. For example, the gate cut GC may be spaced apart from the active pattern F in the second horizontal direction DR2. For example, an upper surface of the gate cut GC may be formed to be coplanar with each of the upper surface of the third interlayer insulating layer 130 and the upper surface of the first capping pattern 123_1. The gate cut GC may be extended to the inside of the substrate 10. The gate cut GC may separate or divide each of the first gate electrode G1 and the second gate electrode G2 in the second horizontal direction DR2.

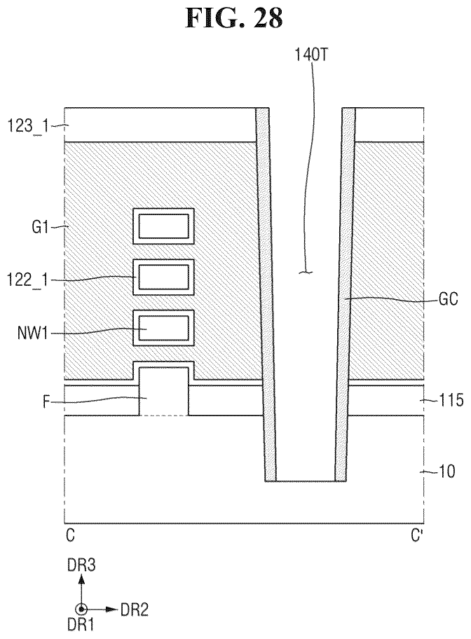

Referring to FIGS. 27 to 29, a power rail via trench 140T may be formed inside the gate cut GC. For example, a portion of the gate cut GC may be removed to form the power rail via trench 140T. A sidewall of the power rail via trench 140T may be at least partially surrounded by the gate cut GC. The substrate 10 may be exposed through a lower surface of the power rail via trench 140T.

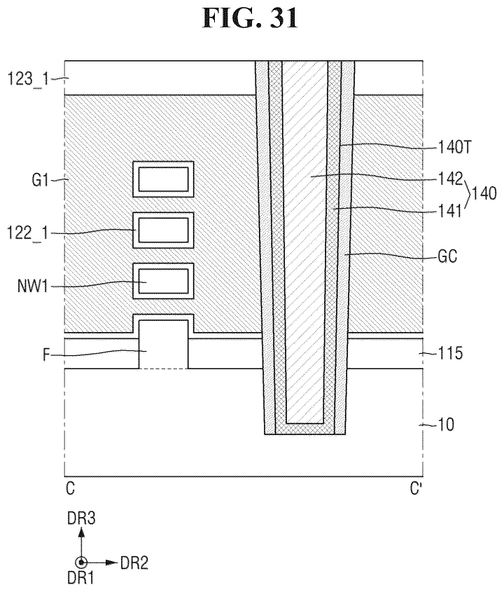

Referring to FIGS. 30 to 32, a power rail via 140 may be formed inside the power rail via trench 140T. For example, a power rail via barrier layer 141 may be formed along a sidewall and a bottom surface of the power rail via trench 140T. Subsequently, a power rail via filling layer 142 may be formed to fill a remaining space of the power rail via trench 140T and may be formed on the power rail via barrier layer 141. For example, each of an uppermost surface of the power rail via barrier layer 141 and an upper surface of the power rail via filling layer 142 may be formed to be coplanar with the upper surface of the gate cut GC.

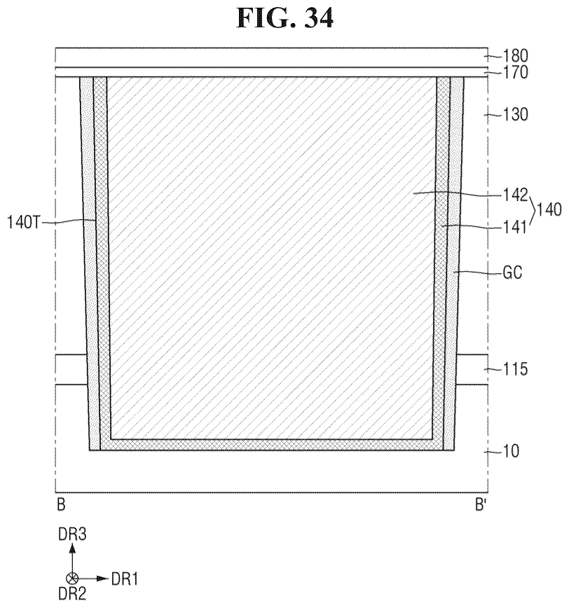

Referring to FIGS. 33 to 36, a first gate contact CB1 connected to the first gate electrode G1 may be formed by passing through the first capping pattern 123_1 in the vertical direction DR3, and a second gate contact CB2 connected to the second gate electrode G2 may be formed by passing through the second capping pattern 123_2 in the vertical direction DR3. For example, holes may be formed in the first capping pattern 123_1 and the second capping pattern 123_2 for the first gate contact CB1 and the second gate contact CB2 to be formed.

In addition, a source/drain contact CA connected to the source/drain region SD may be formed by passing through the third interlayer insulating layer 130 in the vertical direction DR3. For example, while a trench for forming the source/drain contact CA is being formed, a portion of the gate cut GC and a portion of the sidewall of the power rail via 140 may be etched. The sidewall of the power rail via filling layer 142 may be exposed by the trench for forming the source/drain contact CA. Subsequently, the source/drain contact CA may be formed in the trench for forming the source/drain contact CA. As a result, the source/drain contact CA may be formed to be disposed on the sidewall of the power rail via filling layer 142. For example, the source/drain contact CA may be formed to be in contact with the sidewall of the power rail via filling layer 142. A silicide layer 160 may be formed between the source/drain region SD and the source/drain contact CA.

Subsequently, an etch stop layer 170 and a fourth interlayer insulating layer 180 may be sequentially formed on the third interlayer insulating layer 130, the first and second capping patterns 123_1 and 123_2, the first and second gate contacts CB1 and CB2, the source/drain contact CA, the gate cut GC, and the power rail via 140, respectively. Subsequently, a first via V1, a second via V2 and a third via V3, which are respectively connected to the first gate contact CB1, the second gate contact CB2 and the source/drain contact CA, may be formed by passing through the fourth interlayer insulating layer 180 and the etch stop layer 170 in the vertical direction DR3.

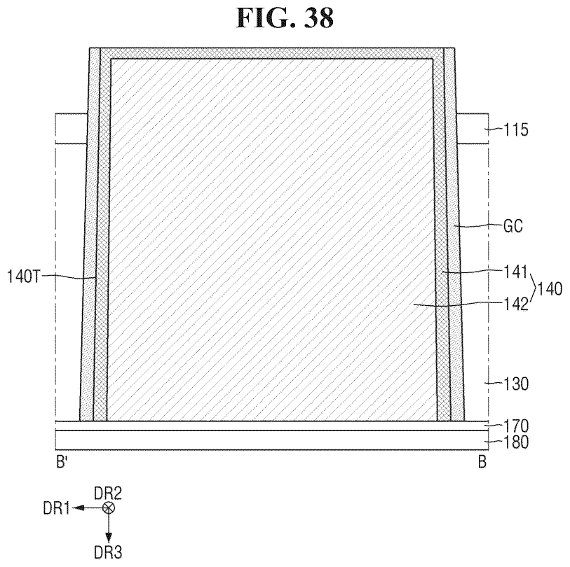

Referring to FIGS. 37 to 40, after the manufacturing process shown in FIGS. 33 to 36 is performed, top and bottom may be reversed. The substrate (10 of FIGS. 33 to 36) may be removed in a state that top and bottom are reversed. For example, the structure is turned upside down.

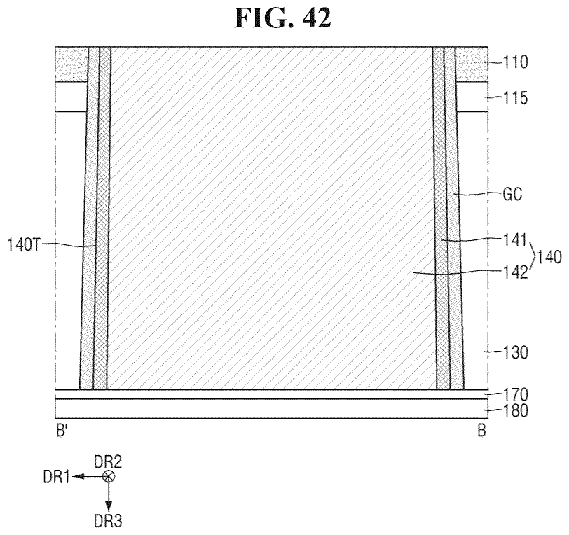

Referring to FIGS. 41 to 44, a second interlayer insulating layer 110 may be formed on the field insulating layer 115 and the active pattern F to cover the gate cut GC and the power rail via 140. Subsequently, a portion of the second interlayer insulating layer 110, a portion of the gate cut GC and a portion of the power rail via 140 may be etched by performing a planarization process. Through the planarization process, the power rail via filling layer 142 may be exposed. For example, the power rail via barrier layer 141 and the gate cut GC may be exposed through the planarization process.

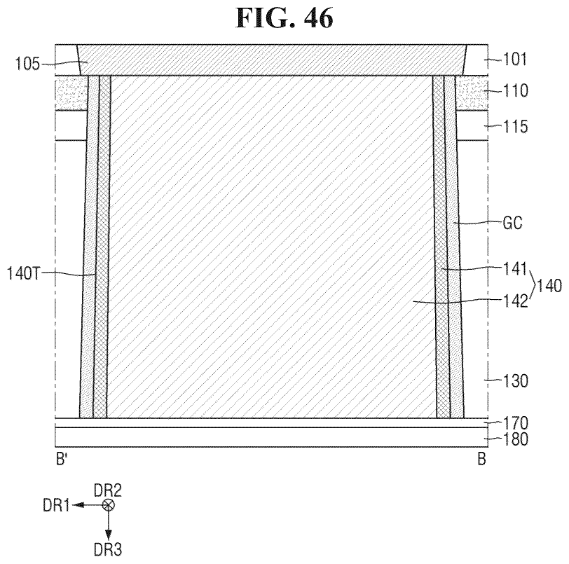

Referring to FIGS. 45 to 48, a first interlayer insulating layer 101 may be formed on the second interlayer insulating layer 110, the gate cut GC and the power rail via 140. Subsequently, after the first interlayer insulating layer 101 is etched to expose each of the gate cut GC and the power rail via 140, a power rail 105 may be formed at the portion from which the first interlayer insulating layer 101 is etched.

Referring to FIGS. 2 to 5, a base substrate 100 may be formed on the first interlayer insulating layer 101 and the power rail 105. After the manufacturing process is performed, the semiconductor device shown in FIGS. 2 to 5 may be manufactured by reversing top and bottom. For example, the semiconductor device shown in FIGS. 2 to 5 may be manufactured by turning the structure in FIGS. 45 to 48 right side up (e.g., rotating the structure 180°).

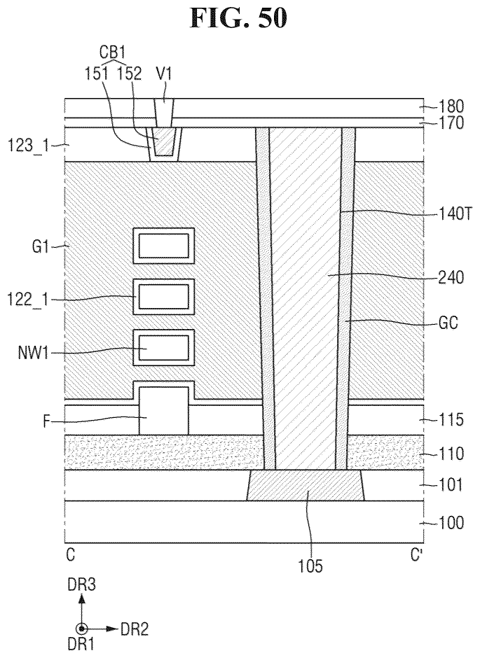

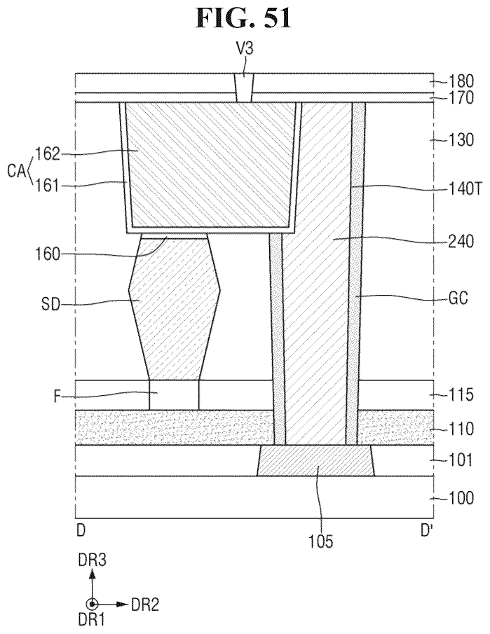

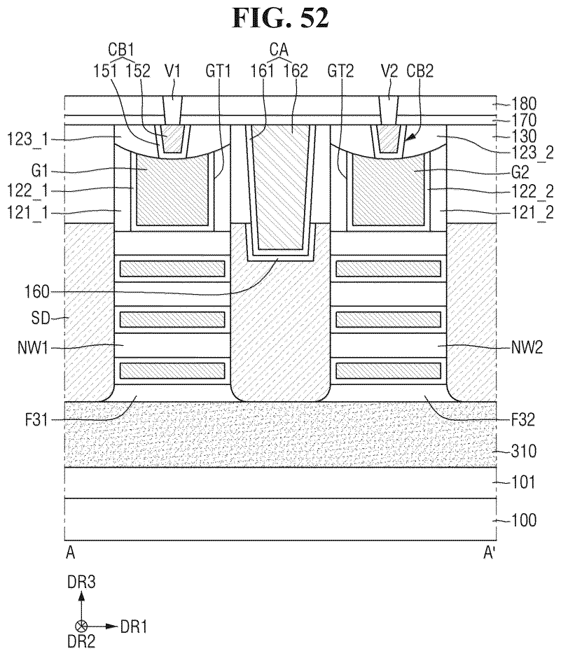

Hereinafter, a semiconductor device according to an embodiment of the present inventive concept will be described with reference to FIGS. 49 to 51. The following description will be based on differences from the semiconductor device shown in FIGS. 1 to 5, and thus, redundant or repetitive descriptions may be omitted or briefly discussed. In addition, like reference numerals may refer to like elements.

FIGS. 49 to 51 are cross-sectional views illustrating a semiconductor device according to an embodiment of the present inventive concept.

Referring to FIGS. 49 to 51, in the semiconductor device according to an embodiment of the present inventive concept, the power rail via 240 may be formed of a single layer.

For example, the power rail via 240 may completely fill the inside of the power rail via trench 140T. The power rail via 240 may be in contact with the gate cut GC. The power rail via 240 may be in contact with the source/drain contact CA. The power rail via 240 may be in contact with the power rail 105. The power rail via 240 may include a conductive material. For example, the power rail via 240 may include the same material as that of the power rail via filling layer 142 shown in FIGS. 1 to 5.

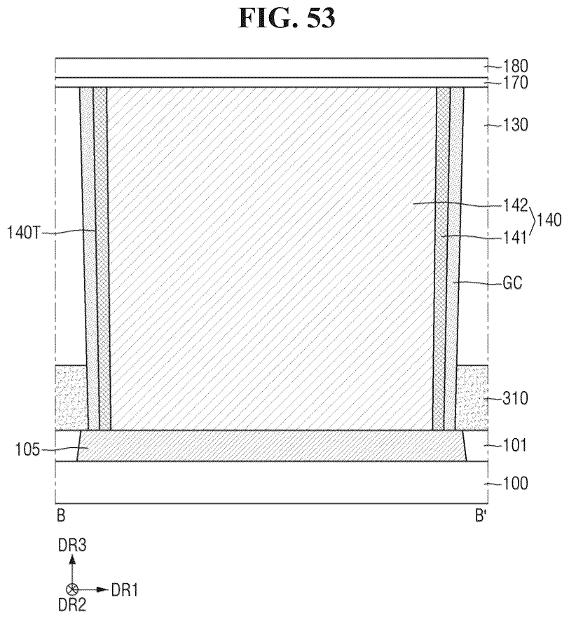

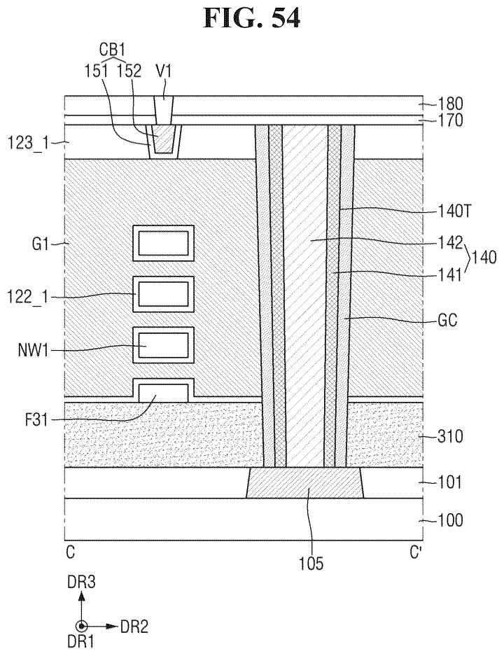

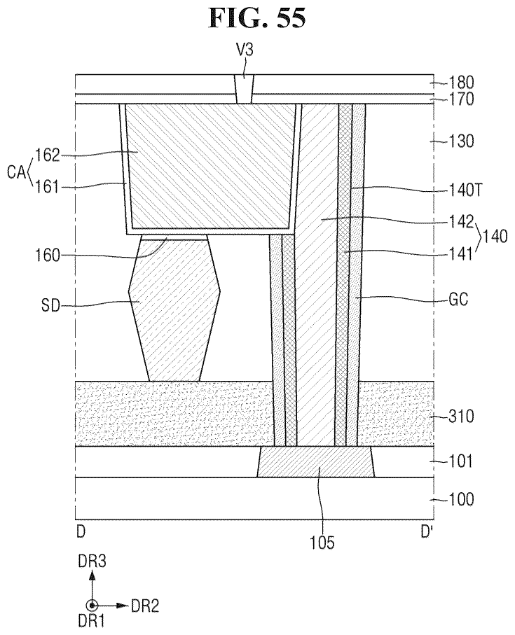

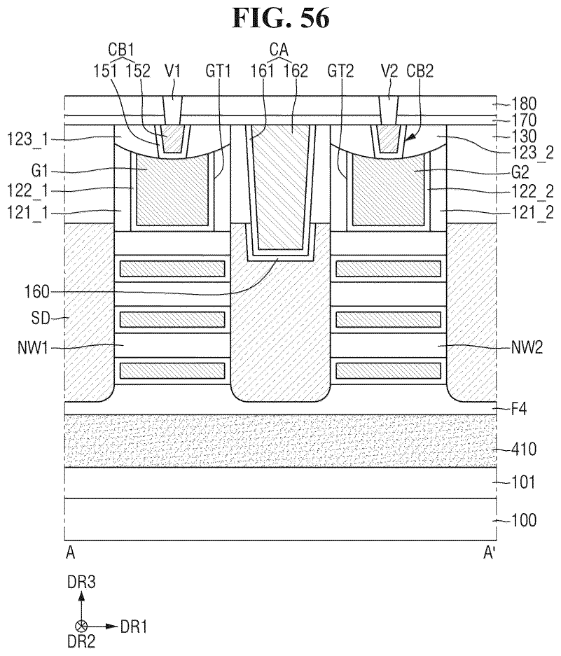

Hereinafter, a semiconductor device according to an embodiment of the present inventive concept will be described with reference to FIGS. 52 to 55. The following description will be based on differences from the semiconductor device shown in FIGS. 1 to 5, and thus, redundant or repetitive descriptions may be omitted or briefly discussed. In addition, like reference numerals may refer to like elements.

FIGS. 52 to 55 are cross-sectional views illustrating a semiconductor device according to an embodiment of the present inventive concept.

Referring to FIGS. 52 to 55, in the semiconductor device according to an embodiment of the present inventive concept, the second interlayer insulating layer 310 may be in contact with the lower surface of the source/drain region SD. In addition, the second interlayer insulating layer 310 may be in contact with the third interlayer insulating layer 130.

The active pattern may include a first active pattern F31 disposed below the plurality of first nanosheets NW1 and a second active pattern F32 disposed below the plurality of second nanosheets NW2. The first active pattern F31 and the second active pattern F32 may be separated from each other in the first horizontal direction DR1. For example, the second active pattern F32 may be spaced apart from the first active pattern F31 in the first horizontal direction DR1. Each of the first and second active patterns F31 and F32 may protrude from the second interlayer insulating layer 310 in the vertical direction DR3.

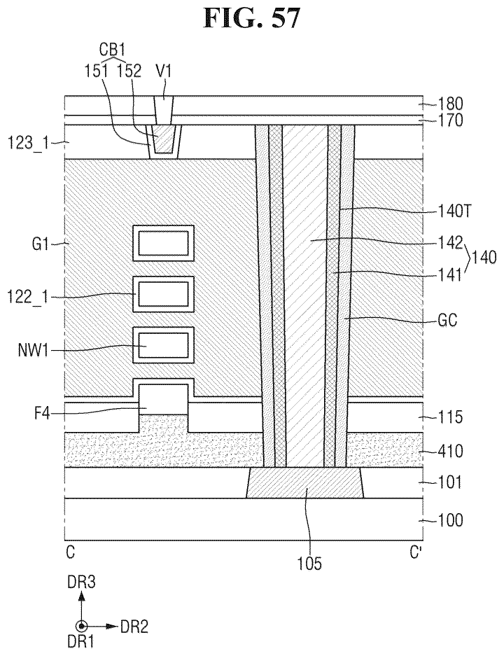

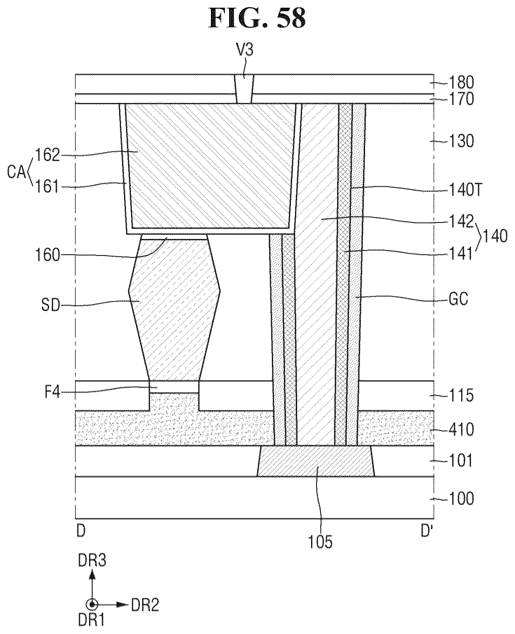

Hereinafter, a semiconductor device according to an embodiment of the present inventive concept will be described with reference to FIGS. 56 to 58. The following description will be based on differences from the semiconductor device shown in FIGS. 1 to 5, and thus, redundant or repetitive descriptions may be omitted or briefly discussed. In addition, like reference numerals may refer to like elements.

FIGS. 56 to 58 are cross-sectional views illustrating a semiconductor device according to some other embodiments of the present disclosure.

Referring to FIGS. 56 to 58, in the semiconductor device according to an embodiment of the present inventive concept, a portion of the second interlayer insulating layer 410 disposed below the active pattern F4 may be protruded in the vertical direction DR3.

For example, a portion of the second interlayer insulating layer 410 disposed below the active pattern F4 may be protruded in the vertical direction DR3 rather than the upper surface of another portion the second interlayer insulating layer 410 that is disposed below the field insulating layer 115. For example, the second interlayer insulating layer 410 includes a portion that protrudes toward the active pattern F4. A sidewall of a portion of the second interlayer insulating layer 410 protruded in the vertical direction DR3 may be surrounded by the field insulating layer 115. For example, a width in the second horizontal direction DR2 of a portion of the second interlayer insulating layer 410 protruded in the vertical direction DR3 may be the same as a width in the second horizontal direction DR2 of the active pattern F4. However, the present inventive concept is not limited thereto. For example, the width in the second horizontal direction DR2 of the portion of the second interlayer insulating layer 410 protruded in the vertical direction DR3 may be different from the width in the second horizontal direction DR2 of the active pattern F4.

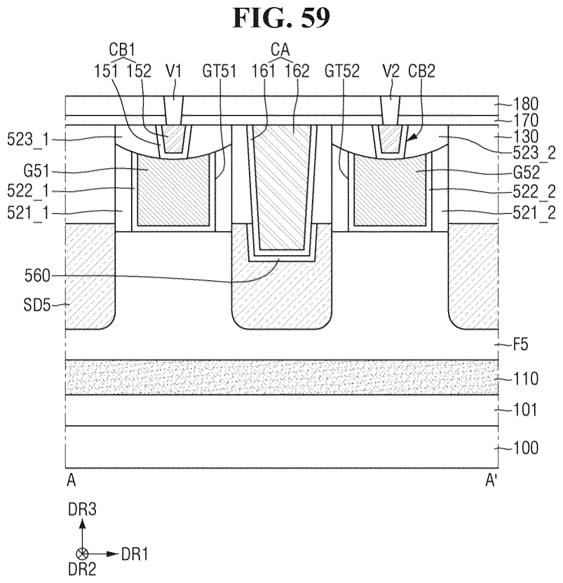

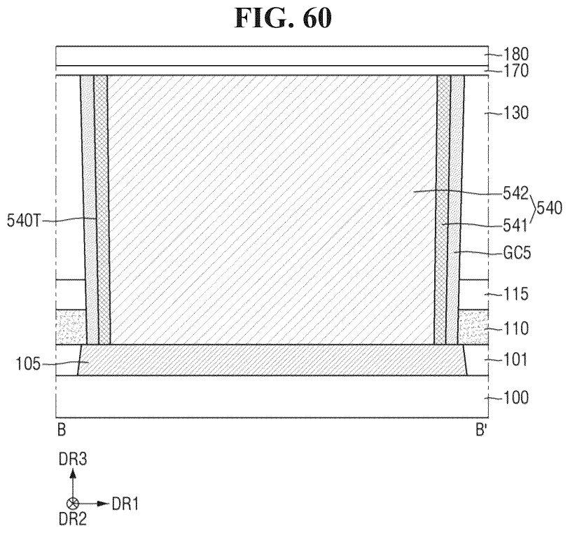

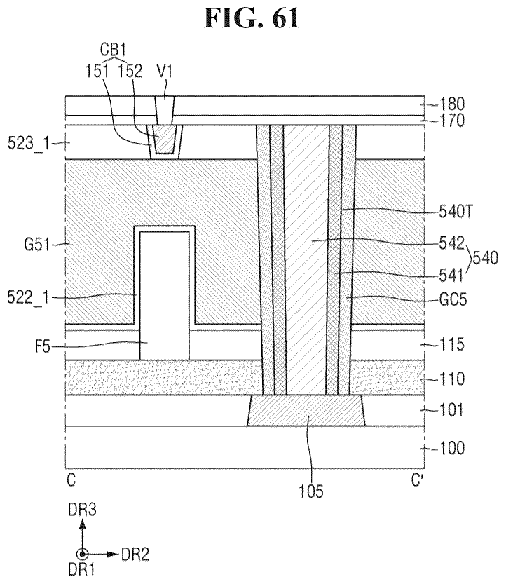

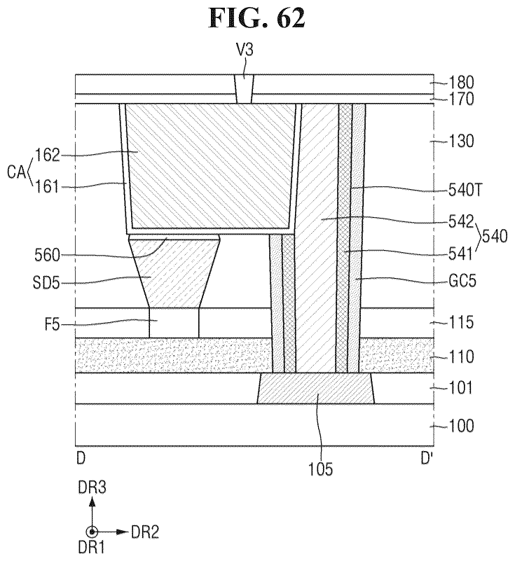

Hereinafter, a semiconductor device according to an embodiment of the present inventive concept will be described with reference to FIGS. 59 to 62. The following description will be based on differences from the semiconductor device shown in FIGS. 1 to 5, and thus, redundant or repetitive descriptions may be omitted or briefly discussed. In addition, like reference numerals may refer to like elements.

FIGS. 59 to 62 are cross-sectional views illustrating a semiconductor device according to an embodiment of the present inventive concept.

Referring to FIGS. 59 to 62, the semiconductor device according to an embodiment of the present inventive concept may include a fin-type transistor (FinFET). For example, the semiconductor device according to an embodiment of the present inventive concept may include a base substrate 100, a first interlayer insulating layer 101, a power rail 105, a second interlayer insulating layer 110, an active pattern F5, a field insulating layer 115, first and second gate electrodes G51 and G52, first and second gate spacers 521_1 and 521_2, first and second gate insulating layers 522_1 and 522_2, first and second capping patterns 523_1 and 523_2, a gate cut GC5, a source/drain region SD5, a third interlayer insulating layer 130, a power rail via 540, first and second gate contacts CB1 and CB2, a source/drain contact CA, a silicide layer 560, an etch stop layer 170, a fourth interlayer insulating layer 180, and first to third vias V1, V2 and V3. Hereinafter, the description of the elements described in FIGS. 1 to 5 that may be assumed to be redundant or repetitive will be omitted. In addition, like reference numerals may refer to like elements

The active pattern F5 may be extended in the first horizontal direction DR1 on the base substrate 100. The active pattern F5 may be protruded from the second interlayer insulating layer 110 in the vertical direction DR3. The first gate spacer 521_1 may be extended in the second horizontal direction DR2 on the active pattern F5 and the field insulating layer 115. A first gate trench GT51 may be provided between the first gate spacers 521_1. The second gate spacer 521_2 may be extended in the second horizontal direction DR2 on the active pattern F5 and the field insulating layer 115. The second gate spacer 521_2 may be spaced apart from the first gate spacer 521_1 in the first horizontal direction DR1. A second gate trench GT52 may be provided between the second gate spacers 521_2.

The first gate insulating layer 522_1 may be disposed along a sidewall and a bottom surface of the first gate trench GT51. The second gate insulating layer 522_2 may be disposed along a sidewall and a bottom surface of the second gate trench GT52. The first gate electrode G51 may fill the inside of the first gate trench GT51 on the first gate insulating layer 522_1. The second gate electrode G52 may fill the inside of the second gate trench GT52 on the second gate insulating layer 522_2. The first capping pattern 5231 may be disposed on the first gate spacer 521_1, the first gate insulating layer 522_1 and the first gate electrode G51, respectively. The second capping pattern 523_2 may be disposed on the second gate spacer 521_2, the second gate insulating layer 522_2 and the second gate electrode G52, respectively.

The source/drain region SD5 may be disposed at both sides of each of the first and second gate electrodes G51 and G52 on the active pattern F5. The silicide layer 560 may be disposed between the source/drain region SD5 and the source/drain contact CA. The gate cut GC5 may be extended in the first horizontal direction DR1 on the power rail 105. For example, the gate cut GC5 may be spaced apart from the active pattern F5 in the second horizontal direction DR2. The gate cut GC5 may separate or divide each of the first and second gate electrodes G51 and G52 in the second horizontal direction DR2. The gate cut GC5 may be in contact with the power rail 105. An upper surface of the gate cut GC5 may be formed to be coplanar with an upper surface of the third interlayer insulating layer 130.

The power rail via 540 may be disposed on the power rail 105. The power rail via 540 may be extended in the first horizontal direction DR1. The power rail via 540 may be disposed inside the power rail via trench 540T formed inside the gate cut GC5. A sidewall of the power rail via 540 may be at least partially surrounded by the gate cut GC5. The sidewall of the power rail via 540 may be in contact with the gate cut GC5. A lower surface of the power rail via 540 may be in contact with the power rail 105. An upper surface of the power rail via 540 may be formed to be coplanar with an upper surface of the gate cut GC5.

The power rail via 540 may include a power rail via barrier layer 541 and a power rail via filling layer 542. The power rail via barrier layer 541 may be disposed along a sidewall of the power rail via trench 540T. The power rail via barrier layer 541 may be in contact with the gate cut GC5. The power rail via barrier layer 541 may be in contact with the power rail 105. The power rail via filling layer 542 may fill the power rail via trench 540T on the power rail via barrier layer 541. The power rail via filling layer 542 may be in contact with the power rail 105.

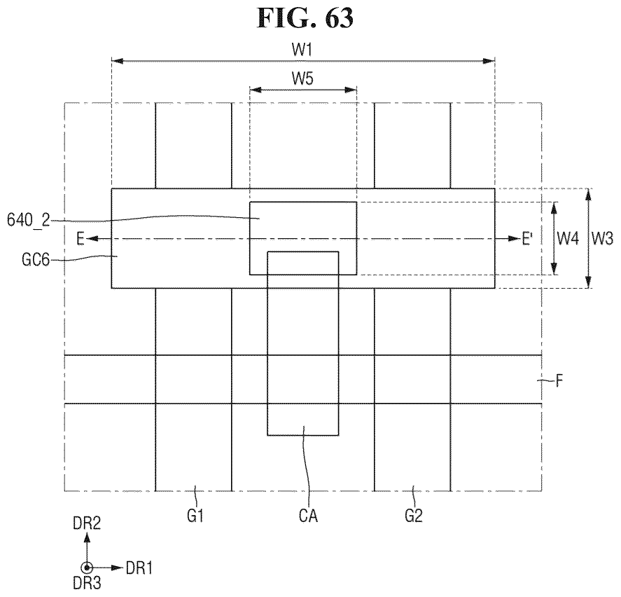

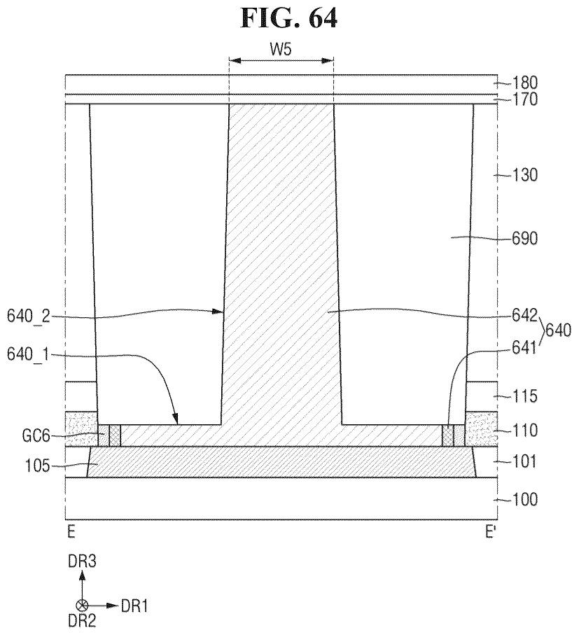

Hereinafter, a semiconductor device according to an embodiment of the present inventive concept will be described with reference to FIGS. 63 and 64. The following description will be based on differences from the semiconductor device shown in FIGS. 1 to 5, and thus, redundant or repetitive descriptions may be omitted or briefly discussed. In addition, like reference numerals may refer to like elements.

FIG. 63 is a schematic layout view illustrating a semiconductor device according to an embodiment of the present inventive concept. FIG. 64 is a cross-sectional view taken along line E-E′ of FIG. 63.

Referring to FIGS. 63 and 64, in the semiconductor device according to an embodiment of the present inventive concept, the power rail via 640 may include a first portion 640_1 that is in contact with the power rail 105, and a second portion 640_2 disposed on the first portion 640_1.

A sidewall of the first portion 640_1 of the power rail via 640 may be surrounded by a gate cut GC6. A width W5 in the first horizontal direction DR1 of the second portion 640_2 of the power rail via 640 may be smaller than a width in the first horizontal direction DR1 of the first portion 640_1 of the power rail via 640. The width W5 in the first horizontal direction DR1 of the second portion 640_2 of the power rail via 640 may be increased as the second portion 640_2 of the power rail via 640 approaches the power rail 105.

The power rail via 640 may include a power rail via barrier layer 641 and a power rail via filling layer 642. The power rail via barrier layer 641 may surround the sidewall of the first portion 640_1 of the power rail via 640. The power rail via barrier layer 641 is not disposed on a sidewall in the first horizontal direction DR1 of the second portion 640_2 of the power rail via 640. In an embodiment of the present inventive concept, the power rail via barrier layer 641 may be disposed along a sidewall in the second horizontal direction DR2 of the second portion 640_2 of the power rail via 640.

For example, the first portion 640_1 of the power rail via 640 may overlap each of the first and second gate electrodes G1 and G2 in the second horizontal direction DR2. For example, the second portion 640_2 of the power rail via 640 might not overlap the first and second gate electrodes G1 and G2 in the second horizontal direction DR2.

In the first portion 640_1 of the power rail via 640, the power rail via filling layer 642 may be disposed between the power rail via barrier layers 641. In the second portion 640_2 of the power rail via 640, both sidewalls in the first horizontal direction DR1 of the power rail via filling layer 642 may be in contact with a fifth interlayer insulating layer 690. For example, the fifth interlayer insulating layer 690 may be disposed between both sidewalls in the first horizontal direction DR1 of the power rail via filling layer 642 and the third interlayer insulating layer 130. The fifth interlayer insulating layer 690 may include at least one of, for example, silicon oxide, silicon nitride, silicon oxynitride, and/or a low dielectric constant material.

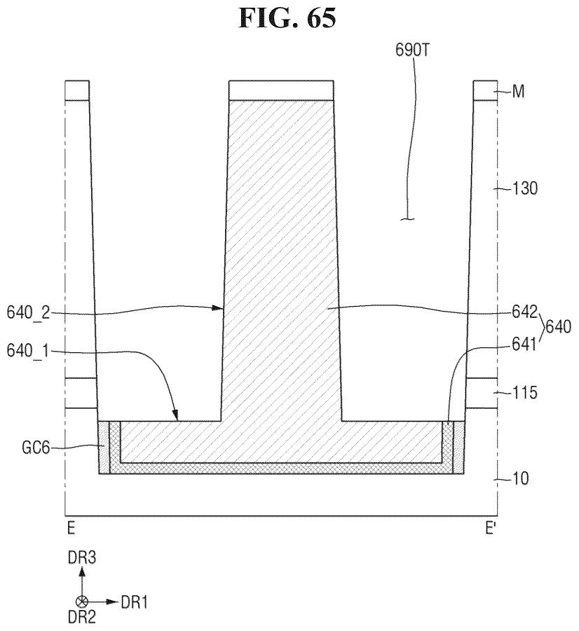

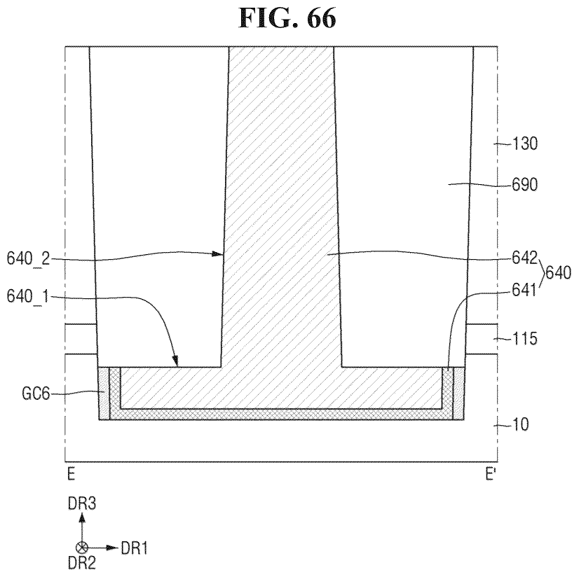

Hereinafter, a method of manufacturing a semiconductor device shown in FIGS. 63 and 64 will be described with reference to FIGS. 65 and 66. The following description will be based on differences from the method of manufacturing a semiconductor device shown in FIGS. 6 to 48, and thus, redundant or repetitive descriptions may be omitted or briefly discussed. In addition, like reference numerals may refer to like elements.

Referring to FIG. 65, after the manufacturing process shown in FIGS. 6 to 32 is performed, a mask pattern M may be formed on the third interlayer insulating layer 130, a portion of the gate cut GC6, and a portion of the power rail via 640. The mask pattern may be formed on the gate cut GC6 disposed on both sidewalls in the second horizontal direction DR2 of the second portion 640_2 of the power rail via 640.

Subsequently, the other portion of the gate cut GC6 and the other portion of the power rail via 640 may be etched using the mask pattern M to form a trench 690T. A portion of the power rail via 640 may remain below the trench 690T. A portion of the power rail via 640 remaining below the trench 690T may be the first portion 640_1 of the power rail via 640. In addition, a portion of the power rail via 640 remaining below the mask pattern M may be the second portion 640_2 of the power rail via 640.

Referring to FIG. 66, after the mask pattern M is removed, the fifth interlayer insulating layer 690 may be filled inside the trench (690T of FIG. 65). Subsequently, the semiconductor device shown in FIGS. 63 and 64 may be manufactured by performing the manufacturing process shown in FIGS. 33 to 48.

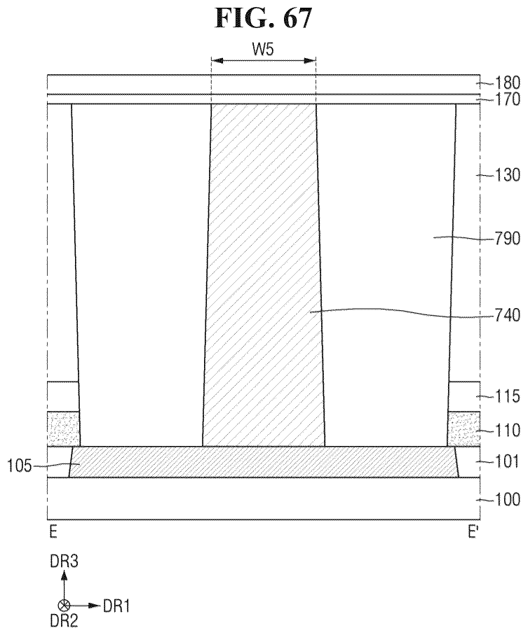

Hereinafter, a semiconductor device according to an embodiment of the present inventive concept will be described with reference to FIG. 67. The following description will be based on differences from the semiconductor device shown in FIGS. 63 and 64, and thus, redundant or repetitive descriptions may be omitted or briefly discussed. In addition, like reference numerals may refer to like elements.

FIG. 67 is a cross-sectional view illustrating a semiconductor device according to an embodiment of the present inventive concept.

Referring to FIG. 67, in the semiconductor device according to an embodiment of the present inventive concept, a fifth interlayer insulating layer 790 may be in contact with the power rail 105. Both sidewalls in the first horizontal direction DR1 of a power rail via 740 may have a continuous slope profile. A width W5 in the first horizontal direction DR1 of the power rail via 740 may be increased as the power rail via 740 approaches the power rail 105. As an example, the power rail via 740 might not overlap the first gate electrode G1 and the second gate electrode G2 in the second horizontal direction DR2.

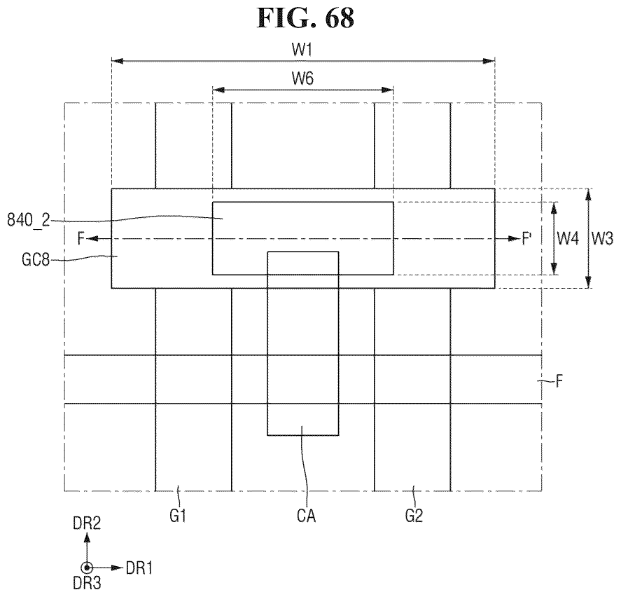

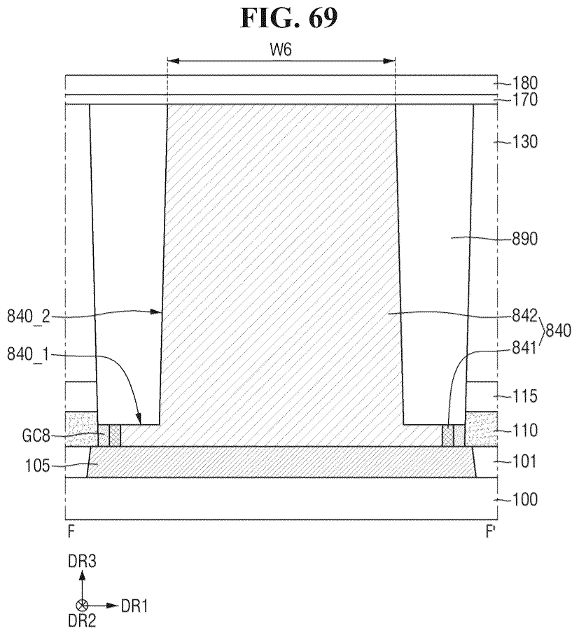

Hereinafter, a semiconductor device according to an embodiment of the present inventive concept will be described with reference to FIGS. 68 and 69. The following description will be based on differences from the semiconductor device shown in FIGS. 1 to 5, and thus, redundant or repetitive descriptions may be omitted or briefly discussed. In addition, like reference numerals may refer to like elements.

FIG. 68 is a schematic layout view illustrating a semiconductor device according to an embodiment of the present inventive concept. FIG. 69 is a cross-sectional view taken along line F-F′ of FIG. 68.

Referring to FIGS. 68 and 69, in the semiconductor device according to an embodiment of the present inventive concept, a power rail via 840 may include a first portion 840_1 that is in contact with the power rail 105, and a second portion 840_2 disposed on the first portion 840_1.

A sidewall of the first portion 840_1 of the power rail via 840 may be at least partially surrounded by a gate cut GC8. A width W6 in the first horizontal direction DR1 of the second portion 840_2 of the power rail via 840 may be smaller than a width in the first horizontal direction DR1 of the first portion 840_1 of the power rail via 840. As the second portion 840_2 of the power rail via 840 approaches the power rail 105, the width W6 in the first horizontal direction DR1 of the second portion 840_2 of the power rail via 840 may be increased.

The power rail via 840 may include a power rail via barrier layer 841 and a power rail via filling layer 842. The power rail via barrier layer 841 may at least partially surround the sidewall of the first portion 840_1 of the power rail via 840. The power rail via barrier layer 841 is not disposed on the sidewall in the first horizontal direction DR1 of the second portion 840_2 of the power rail via 840. The power rail via barrier layer 841 may be disposed along a sidewall in the second horizontal direction DR2 of the second portion 840_2 of the power rail via 840.

For example, the first portion 840_1 of the power rail via 840 may overlap each of the first and second gate electrodes G1 and G2 in the second horizontal direction DR2. For example, at least a portion of the second portion 840_2 of the power rail via 840 may overlap each of the first and second gate electrodes G1 and G2 in the second horizontal direction DR2.

In the first portion 840_1 of the power rail via 840, the power rail via filling layer 842 may be disposed between the power rail via barrier layers 841. In the second portion 840_2 of the power rail via 840, both sidewalls in the first horizontal direction DR1 of the power rail via filling layer 842 may be in contact with the fifth interlayer insulating layer 890. For example, the fifth interlayer insulating layer 890 may be disposed between both sidewalls in the first horizontal direction DR1 of the power rail via filling layer 842 and the third interlayer insulating layer 130. The fifth interlayer insulating layer 890 may include at least one of, for example, silicon oxide, silicon nitride, silicon oxynitride, or a low dielectric constant material.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor device comprising:
a base substrate;
a first interlayer insulating layer disposed on the base substrate;
a power rail disposed inside the first interlayer insulating layer;
an active pattern extended in a first horizontal direction and disposed on the first interlayer insulating layer;
a gate electrode extended in a second horizontal direction different from the first horizontal direction and disposed on the active pattern;
a gate cut extended in the first horizontal direction and disposed on the power rail, wherein the gate cut separates the gate electrode; and
a power rail via disposed inside the gate cut, wherein the power rail via is overlapped by the power rail.

2. The semiconductor device of claim 1, wherein a width in the first horizontal direction of the gate cut is greater than a width in the first horizontal direction of the power rail via.

3. The semiconductor device of claim 1, wherein a width in the second horizontal direction of the gate cut is greater than a width in the second horizontal direction of the power rail via.

4. The semiconductor device of claim 1, wherein the gate cut is in contact with the power rail.

5. The semiconductor device of claim 1, wherein a sidewall of the power rail via is at least partially surrounded by the gate cut.

6. The semiconductor device of claim 1, further comprising a source/drain region disposed on at least one side of the gate electrode; and
a source/drain contact connected to the source/drain region, wherein the source/drain contact is in contact with a sidewall of the power rail via.

7. The semiconductor device of claim 6, wherein an upper surface of the source/drain contact is coplanar with an upper surface of the power rail via.

8. The semiconductor device of claim 6, further comprising a second interlayer insulating layer disposed between the first interlayer insulating layer and the active pattern, wherein the second interlayer insulating layer is in contact with a lower surface of the source/drain region.

9. The semiconductor device of claim 1, wherein at least a portion of the power rail via overlaps the gate electrode in the second horizontal direction.

10. The semiconductor device of claim 1, wherein the power rail via comprises:
a power rail via barrier layer disposed along a sidewall of a power rail via trench formed inside the gate cut, wherein the power rail via barrier layer is disposed on the gate cut; and
a power rail via filling layer filling the power rail via trench and disposed on the power rail via barrier layer, wherein the power rail via filling layer is disposed on the power rail.

11. The semiconductor device of claim 1, further comprising a plurality of nanosheets stacked on each other and spaced apart from each other in a vertical direction on the active pattern and surrounded by the gate electrode.

12. The semiconductor device of claim 1, further comprising:
a second interlayer insulating layer disposed on the first interlayer insulating layer; and
a field insulating layer at least partially surrounding a sidewall of the active pattern on the second interlayer insulating layer,
wherein a portion of the second interlayer insulating layer disposed below the active pattern is protruded in a vertical direction.

13. The semiconductor device of claim 1, wherein the power rail via comprises:
a first portion being in contact with the power rail; and
a second portion disposed on the first portion, and
a width in the first horizontal direction of the second portion of the power rail via is increased as the second portion of the power rail via approaches the power rail.

14. The semiconductor device of claim 1, wherein a width in the first horizontal direction of the power rail via is increased as the power rail via approaches the power rail.

15. A semiconductor device comprising:
a base substrate;
a power rail extended in a first horizontal direction and disposed on the base substrate;
a gate electrode extended in a second horizontal direction different from the first horizontal direction and disposed on the power rail;
a gate cut extended in the first horizontal direction and disposed on the power rail, wherein the gate cut separates the gate electrode, and is in contact with the power rail;
a power rail via disposed inside the gate cut, and in contact with the power rail;
a source/drain region disposed on at least one side of the gate electrode; and
a source/drain contact disposed on the source/drain region, wherein the source/drain contact is in contact with a sidewall of the power rail via,
wherein a width in the first horizontal direction of the gate cut is greater than a width in the first horizontal direction of the power rail via, and
a width in the second horizontal direction of the gate cut is greater than a width in the second horizontal direction of the power rail via.

16. The semiconductor device of claim 15, further comprising:
a first interlayer insulating layer at least partially surrounding the power rail and disposed on the base substrate;
a second interlayer insulating layer disposed on the first interlayer insulating layer;
an active pattern extended in the first horizontal direction between the second interlayer insulating layer and the gate electrode;
a field insulating layer at least partially surrounding a sidewall of the active pattern and disposed on the second interlayer insulating layer; and
a third interlayer insulating layer covering the source/drain region and disposed on the field insulating layer,
wherein the gate cut passes through the second interlayer insulating layer, the field insulating layer and the third interlayer insulating layer in a vertical direction, and
an upper surface of the power rail via is coplanar with an upper surface of the third interlayer insulating layer.

17. The semiconductor device of claim 15, wherein an upper surface of the source/drain contact is coplanar with an upper surface of the power rail via.

18. The semiconductor device of claim 15, wherein the power rail via comprises:
a power rail via barrier layer disposed along a sidewall of a power rail via trench formed inside the gate cut, and is in contact with the gate cut; and
a power rail via filling layer filling the power rail via trench and disposed on the power rail via barrier layer, wherein the power rail via filling layer contacts the power rail.

19. The semiconductor device of claim 15, wherein the power rail via does not overlap the gate electrode in the second horizontal direction.

20. A semiconductor device comprising:
a base substrate;
a first interlayer insulating layer disposed on the base substrate;
a power rail extended in a first horizontal direction inside the first interlayer insulating layer;
a second interlayer insulating layer disposed on the first interlayer insulating layer;
an active pattern extended in the first horizontal direction and disposed on the second interlayer insulating layer;
a plurality of nanosheets stacked on each other and spaced apart from each other in a vertical direction on the active pattern;
a field insulating layer at least partially surrounding a sidewall of the active pattern on the second interlayer insulating layer;
a gate electrode extended in a second horizontal direction different from the first horizontal direction and disposed on the active pattern, wherein the gate electrode at least partially surrounds the plurality of nanosheets;
a source/drain region disposed on at least one side of the gate electrode;
a gate cut extended in the first horizontal direction and disposed on the power rail, wherein the gate cut passes through the second interlayer insulating layer and the field insulating layer in the vertical direction, wherein the gate cut separates the gate electrode, and is in contact with the power rail;
a power rail via disposed inside the gate cut, and in contact with the power rail; and
a source/drain contact connected to the source/drain region, and in contact with a sidewall of the power rail via,
wherein an upper surface of the source/drain contact is coplanar with an upper surface of the power rail via, and
wherein the power rail via comprises:
a power rail via barrier layer disposed along a sidewall of a power rail via trench formed inside the gate cut, and in contact with the gate cut; and
a power rail via filling layer filling the power rail via trench and disposed on the power rail via barrier layer, wherein the power rail via filling layer is in contact with the power rail.
